(19) United States
(12) Patent Application Publication
(10) Pub. No.: US 2025/0040357 A1
(43) Pub. Date: Jan. 30, 2025

(54) DISPLAY DEVICE AND MANUFACTURING METHOD THEREOF

(71) Applicant: Samsung Display Co., LTD., Yongin-si (KR)

(72) Inventors: HYUNEOK SHIN, Yongin-si (KR); YUNG BIN CHUNG, Yongin-si (KR)

(21) Appl. No.: 18/655,450

(22) Filed: May 6, 2024

(30) Foreign Application Priority Data
Jul. 28, 2023 (KR) 10-2023-0099171

(51) Int. Cl. H10K 59/123; H10K 59/12

(52) U.S. Cl. CPC H10K 59/123; H10K 59/1201

(57) ABSTRACT

A display device includes: a circuit layer; and a light emitting element disposed on the circuit layer. The circuit layer includes: a semiconductor pattern, an insulating layer defining a contact hole therein to expose a portion of the semiconductor pattern, a connecting electrode disposed on the insulating layer and partially disposed in the contact hole, and an auxiliary electrode at least partially disposed in the contact hole and contacting with the connecting electrode and the semiconductor pattern. The connecting electrode does not overlap a portion of the contact hole in a plan view.

This application claims priority to Korean Patent Application No. 10-2023-0099171, filed on Jul. 28, 2023, and all the benefits accruing therefrom under 35 U.S.C. § 119, the content of which in its entirety is herein incorporated by reference.

### BACKGROUND

Embodiments of the present disclosure described herein relate to a display device and a manufacturing method thereof, and more particularly, relate to a display device having high resolution characteristics and a method for manufacturing the same.

A display device includes a plurality of pixels and drive circuits (e.g., a scan drive circuit and a data drive circuit) that control the plurality of pixels. Each of the plurality of pixels includes a display element and a pixel drive circuit that controls the display element. The pixel drive circuit may include a plurality of organically connected transistors.

With a gradual increase in the resolutions of display devices, the numbers of signal lines and connecting electrodes that connect display elements and transistors to be arranged within a unit area are increased, and the degree of integration of drive circuits included in pixels is raised.

### SUMMARY

Embodiments of the present disclosure provide a high-resolution display device for preventing a defect in connection between electrodes even though a small contact hole is provided.

According to an embodiment, a display device includes: a circuit layer and a light emitting element disposed on the circuit layer. The circuit layer includes a semiconductor pattern, an insulating layer defining a contact hole therein to expose a portion of the semiconductor pattern, a connecting electrode disposed on the insulating layer and partially disposed in the contact hole, and an auxiliary electrode at least partially disposed in the contact hole and contacting with the connecting electrode and the semiconductor pattern. The connecting electrode does not overlap a portion of the contact hole in a plan view.

The auxiliary electrode may include: a first auxiliary portion, which makes contact with an inner surface of the insulating layer defining the contact hole and covers an entirety of the inner surface of the insulating layer; a second auxiliary portion, which makes contact with the portion of the semiconductor pattern exposed from the insulating layer and covers an entirety of the portion of the semiconductor pattern; and a third auxiliary portion, which makes contact with a portion of an upper surface of the insulating layer.

The connecting electrode may include: a first connecting portion, which makes contact with the third auxiliary portion; and a second connecting portion, which extends downward from the first connecting portion and makes contact with the first auxiliary portion.

An outer surface of the auxiliary electrode and an outer surface of the connecting electrode may be aligned with each other. The outer surface of the auxiliary electrode may be included in the third auxiliary portion, and the outer surface of the connecting electrode may be included in the first connecting portion.

The connecting electrode may include: a 1-1st connecting electrode layer disposed on the auxiliary electrode and which includes aluminum; and a 2-1st connecting electrode layer disposed on the 1-1st connecting electrode layer and which includes titanium.

The display device may further include: a dummy electrode disposed on the second auxiliary portion in the contact hole. The dummy electrode may include: a 1-1st dummy electrode layer spaced apart from the 1-1st connecting electrode layer and which includes the same material as the 1-1st connecting electrode layer; and a 2-1st dummy electrode layer disposed on the 1-1st dummy electrode layer and spaced apart from the 2-1st connecting electrode layer and which includes the same material as the 2-1st connecting electrode layer.

All of the auxiliary electrode may be disposed in the contact hole and may cover the entirety of an inner surface of the insulating layer defining the contact hole, and the semiconductor pattern may include a portion exposed from the auxiliary electrode.

The connecting electrode may include: a lower connecting electrode layer, which makes contact with an upper surface of the insulating layer and includes titanium; a 1-2nd connecting electrode layer disposed on the lower connecting electrode layer and which includes aluminum; and a 2-2nd connecting electrode layer disposed on the 1-2nd connecting electrode layer and which includes titanium.

The display device may further include: a dummy electrode disposed on an upper surface of the semiconductor pattern in the contact hole. An edge of the dummy electrode may make contact with the auxiliary electrode.

The dummy electrode may include: a lower dummy electrode layer, which makes contact with the upper surface of the semiconductor pattern and includes the same material as the lower connecting electrode layer and is spaced apart from the lower connecting electrode layer; a 1-2nd dummy electrode layer disposed on the lower dummy electrode layer, spaced apart from the 1-2nd connecting electrode layer and which includes the same material as the 1-2nd connecting electrode layer; and a 2-2nd dummy electrode layer disposed on the 1-2nd dummy electrode layer, spaced apart from the 2-2nd connecting electrode layer and which includes the same material as the 2-2nd connecting electrode layer.

The auxiliary electrode may include tungsten.

An inner surface of the insulating layer defining the contact hole may have a slope of 80 degrees to 90 degrees with respect to an upper surface of the semiconductor pattern, and the contact hole may have a width greater than 0 micrometer and less than or equal 2.0 micrometers in a sectional view.

According to an embodiment, a display device includes: a circuit layer and a light emitting element disposed on the circuit layer. The circuit layer includes: a semiconductor pattern; an insulating layer defining a contact hole therein to expose a portion of the semiconductor pattern; a connecting electrode disposed on the insulating layer and partially disposed in the contact hole; a dummy electrode disposed on the semiconductor pattern in the contact hole and spaced apart from the connecting electrode; and an auxiliary electrode at least partially disposed in the contact hole and which makes contact with the connecting electrode and the dummy electrode.

According to an embodiment, a method for manufacturing a display device includes: providing a semiconductor pattern and an insulating layer defining a contact hole therein to expose a portion of the semiconductor pattern; forming a preliminary auxiliary electrode on the insulating layer; forming a preliminary connecting electrode on the insulating layer; etching the preliminary connecting electrode to form a connecting electrode partially disposed in the contact hole; and etching the preliminary auxiliary electrode to form an auxiliary electrode at least partially disposed in the contact hole. The auxiliary electrode makes contact with the connecting electrode and the semiconductor pattern, and the connecting electrode does not overlap a portion of the contact hole in a plan view.

The method may further include: forming, on the preliminary connecting electrode, a photoresist pattern which overlaps the contact hole before the etching of the preliminary connecting electrode and after the forming of the preliminary connecting electrode. The etching of the preliminary auxiliary electrode may be simultaneously performed together with the etching of the preliminary connecting electrode.

The forming of the preliminary connecting electrode may include: forming, on the preliminary auxiliary electrode, a 1-1st conductive layer including aluminum; and forming, on the 1-1st conductive layer, a 2-1st conductive layer including titanium.

The etching of the preliminary auxiliary electrode may be performed before the forming of the preliminary connecting electrode and after the forming of the preliminary auxiliary electrode, and the etching of the preliminary auxiliary electrode may be performed through a blanket anisotropic etching process.

The forming of the preliminary connecting electrode may include: forming, on the insulating layer, a lower conductive layer including titanium, forming, on the lower conductive layer, a 1-2nd conductive layer including aluminum, and forming, on the 1-2nd conductive layer, a 2-2nd conductive layer including titanium.

A dummy electrode including the same material as the connecting electrode, disposed in the contact hole and spaced apart from the connecting electrode may be is additionally formed in the forming of the preliminary connecting electrode.

The forming of the preliminary auxiliary electrode may be performed through a chemical vapor deposition process.

### BRIEF DESCRIPTION OF THE FIGURES

The above and other aspects and features of the present disclosure will become apparent by describing in detail embodiments thereof with reference to the accompanying drawings.

FIG. 1A is a perspective view illustrating a display device according to an embodiment of the present disclosure.

FIG. 1B is an exploded perspective view illustrating the display device according to an embodiment of the present disclosure.

FIGS. 1C and 1D are schematic sectional views illustrating display modules according to embodiments of the present disclosure.

FIG. 2A is a perspective view illustrating a display device according to an embodiment of the present disclosure.

FIG. 2B is an exploded perspective view illustrating the display device according to an embodiment of the present disclosure.

FIG. 3 is a sectional view of a display panel according to an embodiment of the present disclosure.

FIG. 4 is a plan view of the display panel according to an embodiment of the present disclosure.

FIG. 5 is an equivalent circuit diagram of a pixel according to an embodiment of the present disclosure.

FIG. 6 is an enlarged sectional view of a portion of the display panel according to an embodiment of the present disclosure.

FIG. 7 is a sectional view of a partial configuration of the display device according to an embodiment of the present disclosure.

FIG. 8 is a sectional view of a partial configuration of the display device according to an embodiment of the present disclosure.

FIGS. 9A to 9F are sectional views illustrating some of the steps of a display device manufacturing method according to an embodiment of the present disclosure.

FIGS. 10A to 10F are sectional views illustrating some of the steps of a display device manufacturing method according to an embodiment of the present disclosure.

### DETAILED DESCRIPTION

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween. Identical reference numerals refer to identical components.

Additionally, in the drawings, the thicknesses, proportions, and dimensions of components are exaggerated for effective description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations defined by related components.

Terms such as “first”, “second”, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

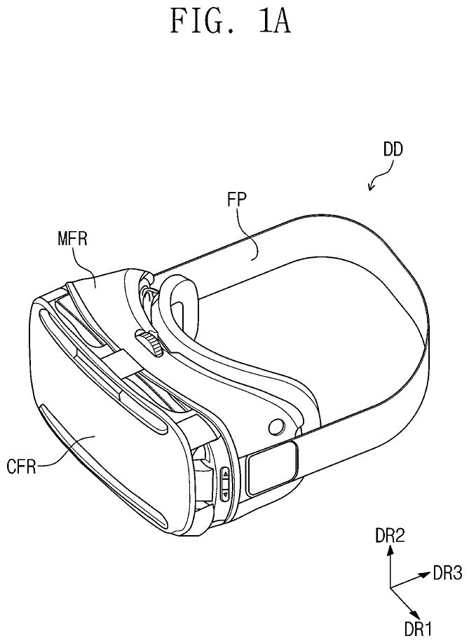

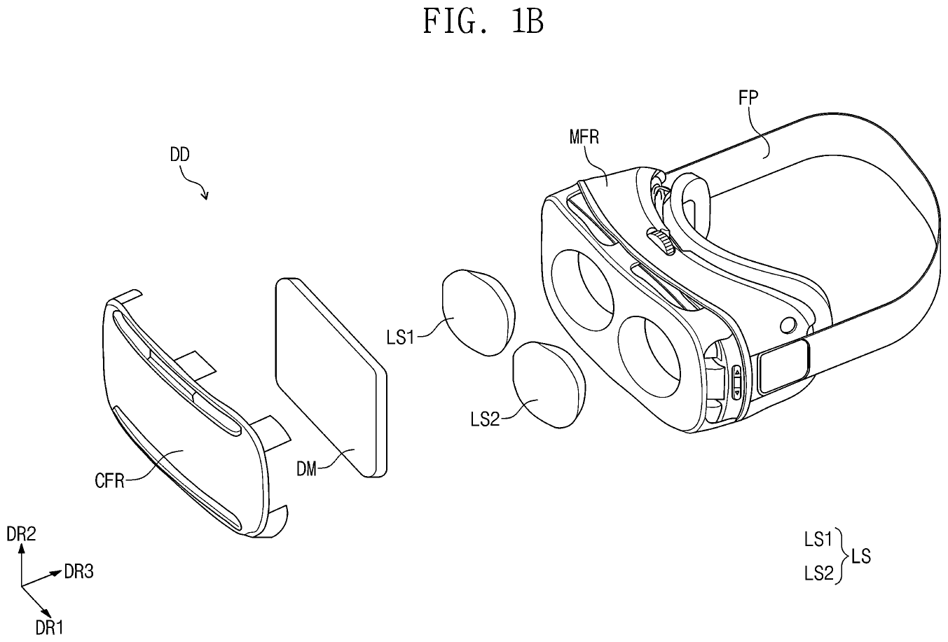

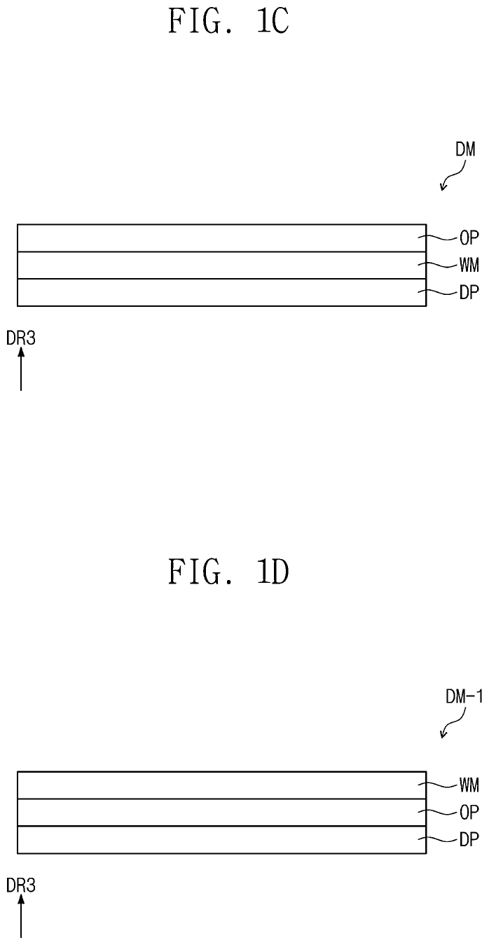

FIG. 1A is a perspective view illustrating a display device according to an embodiment of the present disclosure. FIG. 1B is an exploded perspective view illustrating the display device according to an embodiment of the present disclosure. FIGS. 1C and 1D are schematic sectional views illustrating display modules according to embodiments of the present disclosure.

The display device DD may be a device activated depending on an electrical signal. For example, the display device DD may be a television, a monitor, a billboard, a game machine, a personal computer, a notebook computer, a mobile phone, a tablet computer, a car navigation unit, or a wearable device. However, embodiments are not limited thereto. In FIGS. 1A and 1B, a head mounted display (“HMD”) is illustrated as an example of the display device DD. The head mounted display may be an electronic device that is worn on a user's head and that provides, to the user, a screen on which an image or video is displayed. The head mounted display may include a see-through type HMD that provides augmented reality (“AR”) to the user based on actual external objects and a see-closed type HMD that provides virtual reality (“VR”) to the user with a screen independent of external objects.

Referring to FIGS. 1A and 1B, the display device DD may include a display module DM and a lens unit LS opposite the display module DM. In addition, the display device DD may include a main frame MFR, a cover frame CFR, and a fixing part FP.

The main frame MFR may be a part worn on the user's face. The main frame MFR may have a shape corresponding to the shape of the user's head (face). In an embodiment, for example, the length of the fixing part FP may be adjusted depending on the circumference of the user's head. The fixing part FP may be a structure that facilitates mounting of the main frame MFR and may include a strap, a band, or the like. However, embodiments are not limited thereto, and the fixing part FP may include various forms, such as helmets or eyeglass temples, which are coupled with the main frame MFR.

The main frame MFR may be coupled with the cover frame CFR and may provide a receiving space in which the lens unit LS and the display module DM are mounted.

The lens unit LS may be disposed between the display module DM and the user. The lens unit LS may pass light emitted from the display module DM and may provide the light to the user. In an embodiment, for example, the lens unit LS may include various types of lenses such as a multi-channel lens, a convex lens, a concave lens, a spherical lens, an aspheric lens, a single lens, a compound lens, a normal lens, a narrow-angle lens, a wide-angle lens, a fixed focus lens, a variable focus lens, and the like.

The lens unit LS may include a first lens LS1 and a second lens LS2. The first lens LS1 and the second lens LS2 may be disposed to correspond to the positions of the user's left and right eyes. The first lens LS1 and the second lens LS2 may be accommodated in the main frame MFR.

The display module DM may be provided in a state of being fixed to the main frame MFR. Alternatively, the display module DM may be provided in a state of being detachable from the main frame MFR. The display module DM may provide an image to the user, and the image may include a still image as well as a dynamic image. The display module DM will be described below in more detail.

The cover frame CFR may be disposed on one surface of the display module DM and may protect the display module DM. The cover frame CFR and the lens unit LS may be spaced apart from each other with the display module DM therebetween.

Although first, second, and third directions DR1, DR2, and DR3 are illustrated in FIG. 1A and the following drawings, the directions indicated by the first to third directions DR1, DR2, and DR3 described in this specification may be relative concepts and may be changed to other directions. Furthermore, the directions indicated by the first to third directions DR1, DR2, and DR3 may be described as the first to third directions and may be assigned with identical reference numerals. In this specification, the first direction DR1 and the second direction DR2 may be orthogonal to each other, and the third direction DR3 may be a normal direction to a plane defined by the first direction DR1 and the second direction DR2.

The thickness direction of the display device DD may be a direction parallel to the third direction DR3 that is the normal direction to the plane defined by the first direction DR1 and the second direction DR2. In this specification, front surfaces (or, upper surfaces) and rear surfaces (or, lower surfaces) of members constituting the display device DD may be defined based on the third direction DR3. In this specification, the term “plane” refers to a plane parallel to the plane defined by the first direction DR1 and the second direction DR2, and the “plan view” is a view in a thickness direction (i.e., third direction DR3) of the display device. In this specification, the term “section” refers to a section parallel to the third direction DR3, and the “sectional view” is a view of an object cut by a plane parallel to the thickness direction (i.e., third direction DR3).

Referring to FIGS. 1C and 1D, display modules DM and DM-1 according to embodiments of the present disclosure may include a display panel DP, a window member WM, and an optical member OP.

The display panel DP may be a component that substantially generates an image. An image generated by the display panel DP may be visually recognized by the user from the outside.

The display panel DP may be an emissive display panel and is not particularly limited. In an embodiment, for example, the display panel DP may be an organic light emitting display panel or an inorganic light emitting display panel. The organic light emitting display panel may be a display panel in which an emissive layer includes an organic luminescent material. The inorganic light emitting display panel may be a display panel in which an emissive layer includes quantum dots, quantum rods, or micro LEDs. Hereinafter, it will be exemplified that the display panel DP is an organic light emitting display panel.

The window member WM may be disposed on the display panel DP. The window member WM may include an optically clear insulating material. In an embodiment, for example, the window member WM may include glass or plastic. The window member WM may have a multi-layer structure or a single-layer structure. In an embodiment, for example, the window member WM may include a plurality of plastic films coupled through an adhesive, or may include a glass substrate and a plastic film coupled through an adhesive.

The optical member OP may be disposed on the display panel DP. The optical member OP may be a polarization member, a color filter, or a wavelength filter. The optical member OP may improve display characteristics of the display panel DP by controlling light incident to the optical member OP.

As illustrated in FIG. 1C, in the display module DM of one embodiment, the optical member OP may be disposed on the window member WM. Meanwhile, as illustrated in FIG. 1D, in the display module DM-1 of another embodiment, the optical member OP may be disposed between the window member WM and the display panel DP. Alternatively, unlike in the embodiments illustrated in FIGS. 1C and 1D, the optical member may be omitted.

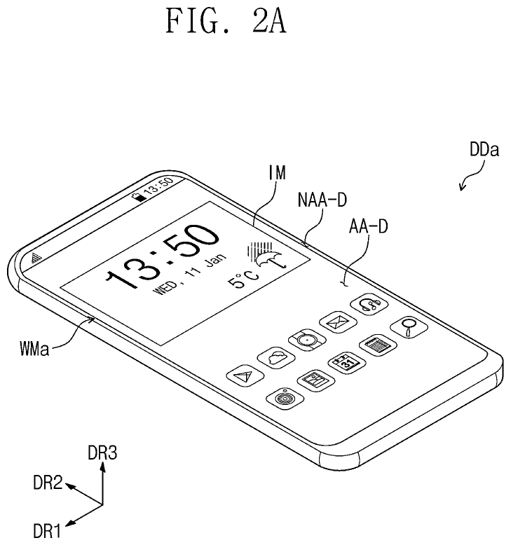

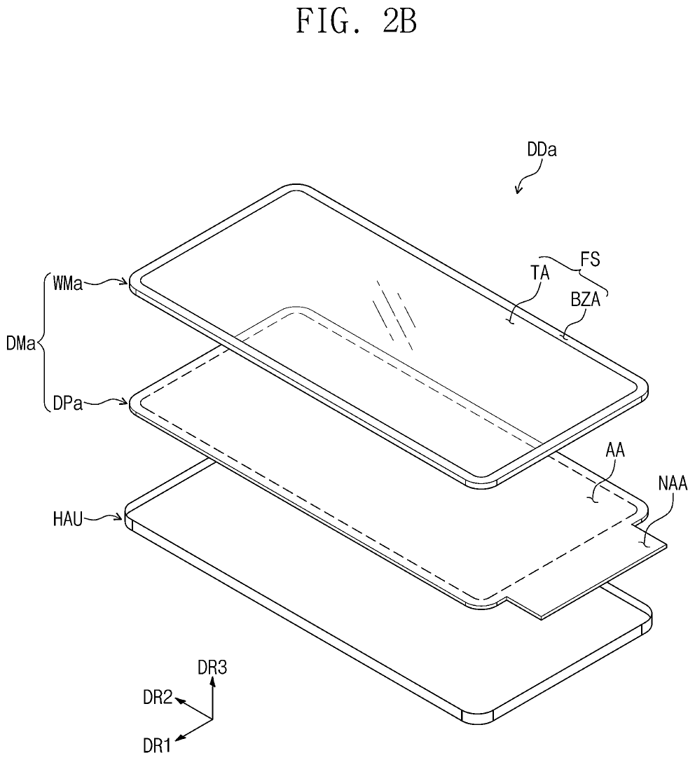

FIG. 2A is a perspective view illustrating a display device according to an embodiment of the present disclosure. FIG. 2B is an exploded perspective view illustrating the display device according to an embodiment of the present disclosure.

FIGS. 2A and 2B illustrate the display device DDa according to an embodiment of the present disclosure. In FIGS. 2A and 2B, a mobile phone is illustrated as an example of the display device DDa.

The display device DDa may display an image IM through an active region AA-D. The active region AA-D may include a plane defined by the first direction DR1 and the second direction DR2. A peripheral region NAA-D is adjacent to the active region AA-D. The peripheral region NAA-D may surround the active region AA-D. However, the peripheral region NAA-D may be disposed adjacent to only one side of the active region AA-D, or may be omitted.

The display device DDa according to this embodiment may include a housing HAU and a display module DMa. The display module DMa according to this embodiment may include a display panel DPa and a window member WMa.

The window member WMa may cover the entire outside of the display module DMa. The window member WMa may include a transmission region TA and a bezel region BZA. The front surface of the window member WMa that includes the transmission region TA and the bezel region BZA may correspond to the front surface of the display device DDa. The transmission region TA may correspond to the active region AA-D of the display device DDa illustrated in FIG. 2A, and the bezel region BZA may correspond to the peripheral region NAA-D of the display device DDa illustrated in FIG. 2A.

The transmission region TA may be an optically transparent region. The bezel region BZA may be a region having a lower light transmittance than the transmission region TA. The bezel region BZA may have a predetermined color. The bezel region BZA may be adjacent to the transmission region TA and may surround the transmission region TA. However, the bezel region BZA may be disposed adjacent to only one side of the transmission region TA, or a portion of the bezel region BZA may be omitted.

The display panel DPa may include an active region AA and a peripheral region NAA. The active region AA may be a region activated depending on an electrical signal. In this embodiment, the active region AA may be a region on which the image IM is displayed. The active region AA of the display panel DPa may correspond to the active region AA-D of the display device DDa illustrated in FIG. 2A, and the peripheral region NAA of the display panel DPa may correspond to the peripheral region NAA-D of the display device DDa illustrated in FIG. 2A. The transmission region TA may overlap at least a portion of the active region AA in a plan view. The peripheral region NAA may be a region covered by the bezel region BZA.

Although not illustrated in FIGS. 2A and 2B, an input sensing unit may be provided on the display panel DPa. The input sensing unit may sense an external input applied from the outside. The external input may be a user input. The user input may include various types of external inputs such as a part of a user's body, light, heat, a pen, or pressure. The input sensing unit may be directly disposed on the display panel DPa, or may be coupled with the display panel DPa through a separate adhesive member.

When one component (or, region, layer, or portion) is described as being “directly disposed” on another component, this means that a third component is not disposed between the one component and the other component. That is, when one component is “directly disposed” on another component, this means that the one component “makes contact with” the other component.

The housing HAU may accommodate the display panel DPa. The housing HAU may be coupled with the window member WMa.

The descriptions of the active region AA-D and the peripheral region NAA-D of the display device DDa, the transmission region TA and the bezel region BZA of the window member WMa, and the active region AA and the peripheral region NAA of the display panel DPa, which have been made with reference to FIGS. 2A and 2B, may be identically applied to the display device DD, the window member WM, and the display panel DP described above with reference to FIGS. 1A to 1D.

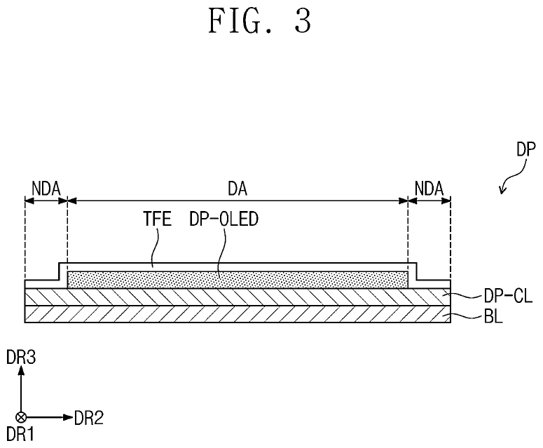

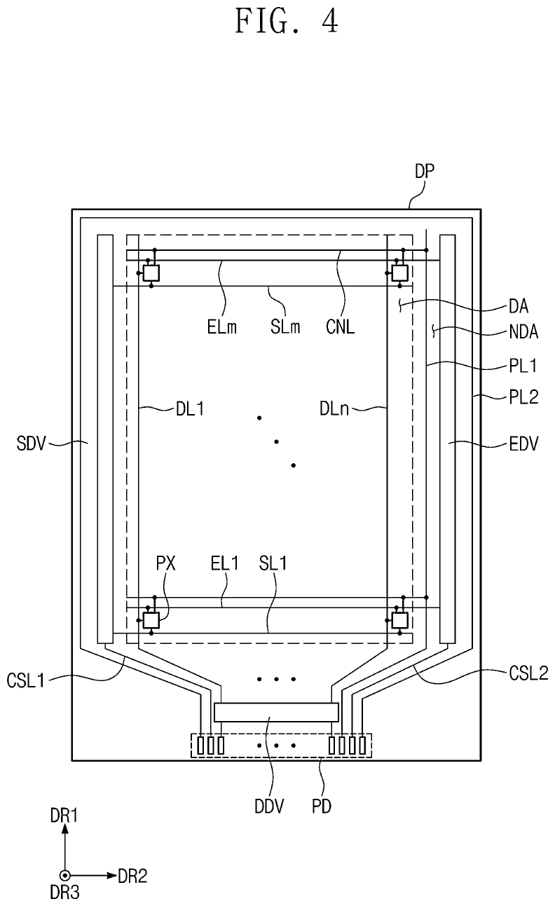

FIG. 3 is a sectional view of a display panel according to an embodiment of the present disclosure. In FIG. 3, a section of the display panel DP viewed in the first direction DR1 is illustrated.

Referring to FIG. 3, the display panel DP may include a base layer BL, and a circuit layer DP-CL disposed on the base layer BL, a display element layer DP-OLED disposed on the circuit layer DP-CL, and a thin film encapsulation layer TFE disposed on the display element layer DP-OLED.

The base layer BL may include a display region DA and a non-display region NDA around the display region DA. The display region DA may correspond to the active region AA of the display panel DPa illustrated in FIG. 2B, and the non-display region NDA may correspond to the peripheral region NAA of the display panel DPa illustrated in FIG. 2B. The base layer BL may include a flexible plastic material such as polyimide (“PI”). The display element layer DP-OLED may be disposed on the display region DA.

A plurality of pixels may be disposed in the circuit layer DP-CL and the display element layer DP-OLED. Each of the pixels may include transistors disposed in the circuit layer DP-CL and a light emitting element disposed in the display element layer DP-OLED and connected to the transistors. A configuration of the pixel will be described below in detail.

The thin film encapsulation layer TFE may be disposed on the circuit layer DP-CL to cover the display element layer DP-OLED. The thin film encapsulation layer TFE may protect the pixels from moisture, oxygen, and external foreign matter.

FIG. 4 is a plan view of the display panel according to an embodiment of the present disclosure.

Referring to FIG. 4, the display device DD may include the display panel DP, a scan driver SDV, a data driver DDV, an emission driver EDV, and a plurality of pads PD.

The display panel DP may have a rectangular shape with long sides extending in the first direction DR1 and short sides extending in the second direction DR2. However, the shape of the display panel DP is not limited thereto. The display panel DP may include a display region DA and a non-display region NDA surrounding the display region DA.

The display panel DP may include a plurality of pixels PX, a plurality of scan lines SL1 to SLm, a plurality of data lines DL1 to DLn, a plurality of emission lines ELI to ELm, first and second control lines CSL1 and CSL2, first and second power lines PL1 and PL2, and connecting lines CNL. Here, “m” and “n” are natural numbers.

The pixels PX may be disposed in the display region DA. The scan driver SDV and the emission driver EDV may be disposed in the non-display regions NDA adjacent to the long sides of the display panel DP, respectively. The data driver DDV may be disposed in the non-display region NDA adjacent to one of the short sides of the display panel DP. The data driver DDV may be adjacent to a lower end of the display panel DP when viewed from above the plane.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The emission lines ELI to ELm may extend in the second direction DR2 and may be connected to the pixels PX and the emission driver EDV.

The first power line PL1 may extend in the first direction DR1 and may be disposed in the non-display region NDA. The first power line PL1 may be disposed between the display region DA and the emission driver EDV.

The connecting lines CNL may extend in the second direction DR2 and may be arranged in the first direction DR1 and connected to the first power line PL1 and the pixels PX. A first voltage may be applied to the pixels PX through the first power line PL1 and the connecting lines CNL connected with each other. The connecting lines CNL may be substantially defined as portions of the first power line PL1 that receives the first voltage.

The second power line PL2 may be disposed in the non-display region NDA and may extend along the long sides of the display panel DP and the other short side of the display panel DP where the data driver DDV is not disposed. The second power line PL2 may be disposed outward of the scan driver SDV and the emission driver EDV.

Although not illustrated, the second power line PL2 may extend toward the display region DA and may be connected to the pixels PX. A second voltage having a lower level than the first voltage may be applied to the pixels PX through the second power line PL2.

The first control line CSL1 may be connected to the scan driver SDV and may extend toward the lower end of the display panel DP. The second control line CSL2 may be connected to the emission driver EDV and may extend toward the lower end of the display panel DP. The data driver DDV may be disposed between the first control line CSL1 and the second control line CSL2.

The pads PD may be disposed in the non-display region NDA adjacent to the lower end of the display panel DP and may be closer to the lower end of the display panel DP than the data driver DDV. The data driver DDV, the first and second power lines PL1 and PL2, and the first and second control lines CSL1 and CSL2 may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling operations of the scan driver SDV, the data driver DDV, and the emission driver EDV and a voltage generator for generating the first and second voltages. The timing controller and the voltage generator may be connected to the corresponding pads PD through a printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines ELI to ELm.

The pixels PX may receive the data voltages in response to the scan signals. The pixels PX may display an image by emitting light having luminance corresponding to the data voltages in response to the emission signals.

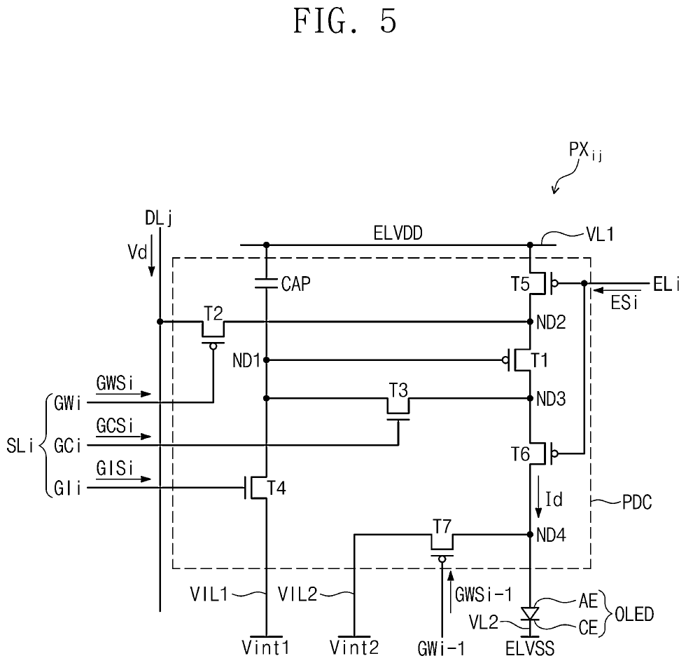

FIG. 5 is an equivalent circuit diagram of a pixel according to an embodiment of the present disclosure. In an embodiment, for example, a pixel PXij connected to the i-th scan line SLi, the i-th emission line ELi, and the j-th data line DLj is illustrated in FIG. 5. Here, “i” and “j” are natural numbers.

Referring to FIG. 5, the pixel PXij may include a light emitting element OLED and a pixel drive circuit PDC electrically connected to the light emitting element OLED. The pixel drive circuit PDC may include transistors T1 to T7 and a capacitor CAP. The transistors T1 to T7 and the capacitor CAP may control the amount of current flowing through the light emitting element OLED, and the light emitting element OLED may generate light having predetermined luminance depending to the amount of current provided thereto.

The i-th scan line SLi may include first to third scan lines GWi, GCi, and Gli. The first scan line GWi that receives the i-th write scan signal GWSi may be defined as the write scan line GWi. The second scan line GCi that receives the i-th compensation scan signal GCSi may be defined as the compensation scan line GCi. The third scan line Gli that receives the i-th initialization scan signal GISi may be defined as the initialization scan line Gli.

The transistors T1 to T7 may include the first to seventh transistors T1 to T7. Each of the first to seventh transistors T1 to T7 may include a source electrode, a drain electrode, and a gate electrode. Hereinafter, the source electrode, the drain electrode, and the gate electrode may be referred to as the source, the drain, and the gate, respectively.

The expression “electrically connected between a transistor and a signal line or between a transistor and a transistor” used herein means that an electrode of the transistor is integrally formed with the signal line or connected with the signal line through a connecting electrode.

The first to seventh transistors T1 to T7 may be transistors having an oxide semiconductor layer or transistors having a low-temperature polycrystalline silicon (“LTPS”) semiconductor layer. The first to seventh transistors T1 to T7 may be N-type transistors or P-type transistors. In an embodiment, for example, the first, second, fifth, sixth, and seventh transistors T1, T2, T5, T6, and T7 may be PMOS transistors having an LTPS semiconductor layer, and the third and fourth transistors T3 and T4 may be NMOS transistors having an oxide semiconductor layer. However, embodiments of the transistors T1 to T7 are not limited thereto. Furthermore, although the pixel drive circuit PDC including the seven transistors T1 to T7 is illustrated as an example, the number of transistors included in the pixel drive circuit PDC is not limited thereto.

The light emitting element OLED may be defined as an organic light emitting element. The light emitting element OLED may include a first electrode AE and a second electrode CE. In an embodiment, for example, the first electrode AE may be an anode, and the second electrode CE may be a cathode. The first electrode AE of the light emitting element OLED may be electrically connected to a first voltage line VL1 that receives a first drive voltage ELVDD. The second electrode CE of the light emitting element OLED may be electrically connected to a second voltage line VL2 that receives a second drive voltage ELVSS.

The first transistor T1 may be electrically connected between the first voltage line VL1 that receives the first drive voltage ELVDD and the light emitting element OLED. The first transistor T1 may include the source connected to a second node ND2, the drain connected to a third node ND3, and the gate connected to a first node ND1. The first transistor T1 may be turned on by a voltage of the first node ND1. The first transistor T1 may receive a data voltage Vd transferred by the data line DLj depending on a switching operation of the second transistor T2 and may supply a drive current Id to the light emitting element OLED. In this embodiment, the first transistor T1 may be defined as a drive transistor.

The second transistor T2 may be electrically connected between the data line DLj and the first transistor T1. The second transistor T2 may include the source connected to the data line DLj, the drain connected to the second node ND2, and the gate connected to the first scan line GWi. The second transistor T2 and the first transistor T1 may be connected through the second node ND2. The second transistor T2 may be turned on by the write scan signal GWSi applied through the first scan line GWi. The data voltage Vd applied to the data line DLj may be transferred to the source of the first transistor T1 by the turned-on second transistor T2. In this embodiment, the second transistor T2 may be defined as a switching transistor.

The third transistor T3 may be electrically connected between the fourth transistor T4 and the first transistor T1. The third transistor T3 may include the source connected to the first node ND1, the drain connected to the third node ND3, and the gate connected to the second scan line GCi. The third transistor T3 and the first transistor T1 may be connected through the third node ND3. The third transistor T3 may be turned on by the compensation scan signal GCSi applied through the second scan line GCi. The gate of the first transistor T1 and the drain of the first transistor T1 may be electrically connected with each other by the turned-on third transistor T3, and the first transistor T1 may be diode-connected. In this embodiment, the third transistor T3 may be defined as a compensation transistor.

The fourth transistor T4 may be electrically connected between a first initialization line VIL1 that receives a first initialization voltage Vint1 and the third transistor T3. The fourth transistor T4 may include the source connected to the first initialization line VIL1, the drain connected to the first node ND1, and the gate connected to the third scan line Gli. The fourth transistor T4 may be turned on by the initialization scan signal GISi applied through the third scan line Gli. The first initialization voltage Vint1 may be transferred to the first node ND1 by the turned-on fourth transistor T4, and the potential of the gate of the first transistor T1 may be initialized. In this embodiment, the fourth transistor T4 may be defined as an initialization transistor.

The fifth transistor T5 may be electrically connected between the first voltage line VL1 that receives the first drive voltage ELVDD and the first transistor T1. The fifth transistor T5 may include the source connected to the first voltage line VL1, the drain connected to the second node ND2, and the gate connected to the emission line ELi.

The sixth transistor T6 may be electrically connected between the first transistor T1 and the light emitting element OLED. The sixth transistor T6 may include the source connected to the third node ND3, the drain connected to the first electrode AE of the light emitting element OLED through a fourth node ND4, and the gate connected to the emission line ELj.

The fifth transistor T5 and the sixth transistor T6 may be turned on by an emission signal ESi applied through the emission line ELi. The light emission time of the light emitting element OLED may be controlled by the emission signal ESi. When the fifth transistor T5 and the sixth transistor T6 are turned on, the drive current Id depending on a voltage difference between the gate voltage of the gate of the first transistor T1 and the first drive voltage ELVDD may be generated. The drive current Id may be supplied to the light emitting element OLED through the sixth transistor T6, and the light emitting element OLED may emit light. In this embodiment, the fifth transistor T5 and the sixth transistor T6 may be defined as emission control transistors.

The seventh transistor T7 may be electrically connected between the sixth transistor T6 and a second initialization line VIL2 that receives a second initialization voltage Vint2. The seventh transistor T7 may include the source connected to the fourth node ND4, the drain connected to the second initialization line VIL2, and the gate connected to a first scan line GWi−1. The gate of the seventh transistor T7 may be connected to the (i−1)th write scan line GWi−1 that is a write scan line before the i-th write scan line GWi. However, without being limited thereto, the gate of the seventh transistor T7 may be electrically connected to a separate fourth scan line.

The seventh transistor T7 may be turned on by the (i−1)th write scan signal GWSi−1 applied through the first scan line GWi−1. The second initialization voltage Vint2 may be transferred to the fourth node ND4 by the turned-on seventh transistor T7. The second initialization voltage Vint2 may have the same level as the first initialization voltage Vint1. However, without being limited thereto, the second initialization voltage Vint2 may have a level different from the level of the first initialization voltage Vint1. In this embodiment, the seventh transistor T7 may be defined as an initialization transistor.

The seventh transistor T7 may improve the ability of the pixel PXij to express black. A portion of the drive current Id may escape through the seventh transistor T7 as a bypass current. When a black image is displayed, a current reduced by the amount of the bypass current escaping from the drive current Id through the seventh transistor T7 may be provided to the light emitting element OLED, and thus the black image may be clearly displayed. That is, the accurate black luminance image may be implemented through the seventh transistor T7, and thus the contrast ratio of the display device DD (refer to FIG. 1) may be improved.

The capacitor CAP may include a first electrode that receives the first drive voltage ELVDD and a second electrode connected to the first node ND1. Charges corresponding to a voltage difference between the first electrode and the second electrode may be stored in the capacitor CAP. When the fifth transistor T5 and the sixth transistor T6 are turned on, the amount of current flowing through the first transistor T1 may be determined depending on the voltage stored in the capacitor CAP.

The configuration of the pixel drive circuit PDC illustrated in FIG. 5 is illustrative, and without being limited thereto, various changes and modifications may be made to the configuration of the pixel drive circuit PDC.

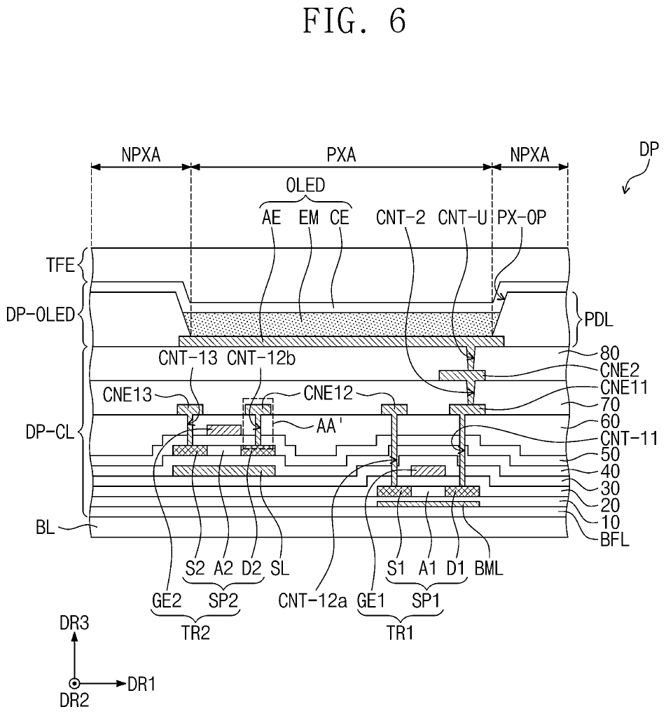

FIG. 6 is an enlarged sectional view of a portion of the display panel according to an embodiment of the present disclosure.

In FIG. 6, the light emitting element OLED and some of the transistors of the pixel drive circuit PDC (refer to FIG. 5) connected to the light emitting element OLED are illustrated. The above description may be applied to the components of the display panel DP illustrated in FIG. 6.

Referring to FIG. 6, the display panel DP may include the base layer BL, the circuit layer DP-CL, the display element layer DP-OLED, and the thin film encapsulation layer TFE.

The base layer BL may provide a base surface on which the circuit layer DP-CL is disposed. The circuit layer DP-CL may include insulating layers BFL and 10 to 80, transistors TR1 and TR2, and connecting electrodes CNE11 to CNE13 and CNE2. The insulating layers BFL and 10 to 80 may include the buffer layer BFL and the first to eighth insulating layers 10 to 80 disposed on the buffer layer BFL. However, insulating layers included in the circuit layer DP-CL are not limited thereto and may vary depending on the configuration of the pixel drive circuit included in the circuit layer DP-CL and a process of the circuit layer DP-CL.

The buffer layer BFL may be disposed on the base layer BL. The buffer layer BF may include at least one inorganic layer. In an embodiment, for example, the buffer layer BFL may include at least one of aluminum oxide, titanium oxide, silicon oxide, silicon nitride, silicon oxy nitride, zirconium oxide, and hafnium oxide. The buffer layer BFL may improve a coupling force between the base layer BL and a semiconductor pattern layer or a conductive pattern layer of the circuit layer DP-CL disposed on the base layer BL.

Each of the first to eighth insulating layers 10 to 80 may include an inorganic layer and/or an organic layer and may have a single-layer structure or a multi-layer structure. The inorganic layer may include at least one of aluminum oxide, titanium oxide, silicon oxide, silicon nitride, silicon oxy nitride, zirconium oxide, and hafnium oxide. However, the material of the inorganic layer is not limited thereto. In an embodiment, the organic layer may include at least one of an acrylic resin, a methacrylic resin, a polyisoprene resin, a vinyl resin, an epoxy resin, a urethane-based resin, a celluosic resin, a siloxane-based resin, a polyamide resin, and a perylene-based resin. However, the material of the organic layer is not limited thereto.

A light blocking pattern BML may be disposed on the buffer layer BFL. The light blocking pattern BML may be directly disposed on the base layer BL when the buffer layer BFL is omitted. The light blocking pattern BML may include molybdenum. The light blocking pattern BML may perform a shielding function. The light blocking pattern BML may block electric potential due to polarization between the insulating layers 10 to 80 disposed on the light blocking pattern BML from affecting the transistors T1 to T7 (refer to FIG. 5).

In FIG. 6, the first type transistor TR1 and the second type transistor TR2 of the pixel drive circuit PDC (refer to FIG. 5) are illustrated. In this embodiment, the first type transistor TR1 may be a silicon thin film transistor, and the second type transistor TR2 may be an oxide thin film transistor. The first type transistor TR1 may be one of the first, second, fifth, sixth, and seventh transistors T1, T2, T5, T6, and T7 described with reference to FIG. 5, and the second type transistor TR2 may be one of the third and fourth transistors T3 and T4. In this embodiment, the first type transistor TR1 and the second type transistor TR2 may be disposed in different layers.

A semiconductor pattern (hereinafter, referred to as the first semiconductor pattern SP1) of the first type transistor TR1 may be disposed on the buffer layer BFL. The first semiconductor pattern SP1 may include a silicon semiconductor. In an embodiment, for example, the silicon semiconductor may include amorphous silicon or polycrystalline silicon. In an embodiment, for example, the first semiconductor pattern SP1 may include low-temperature polycrystalline silicon. However, a material included in the first semiconductor pattern SP1 is not limited thereto as long as the first semiconductor pattern SP1 has semiconductor properties.

FIG. 6 illustrates only a portion of the first semiconductor pattern SP1 disposed on the buffer layer BFL, and the first semiconductor pattern SP1 may be additionally disposed in other regions. The first semiconductor pattern SP1 may be arranged across the pixels PX (refer to FIG. 4) according to a specific rule. The first semiconductor pattern SP1 may have different electrical properties depending on whether the first semiconductor pattern SP1 is doped or not. The first semiconductor pattern SP1 may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an un-doped region, or may be a region more lightly doped than the first region.

The conductivity of the first region may be higher than the conductivity of the second region, and the first region may substantially serve as an electrode or a signal line. The second region may substantially correspond to an active (or, channel) region of the first type transistor TR1. In other words, one portion of the first semiconductor pattern SP1 may be the active region of the first type transistor TR1, another portion may be a source or a drain of the first type transistor TR1, and the other portion may be a connecting electrode or a connecting signal line.

A source region S1, an active region A1, and a drain region D1 of the first type transistor TR1 may be formed from the first semiconductor pattern SP1. The source region S1 and the drain region D1 may extend from the active region AC1 in opposite directions in a sectional view.

The first insulating layer 10 may be disposed on the buffer layer BFL. The first insulating layer 10 may cover the light blocking pattern BML. The second insulating layer 20 may be disposed on the first insulating layer 10. The second insulating layer 20 may cover the first semiconductor pattern SP1.

A gate electrode (hereinafter, referred to as the first gate electrode GE1) of the first type transistor TR1 may be disposed on the second insulating layer 20. The first gate electrode GE1 may overlap the active region A1 in a plan view. In an embodiment, the first gate electrode GE1 may function as a mask in a process of doping the first semiconductor pattern SP1.

Although FIG. 6 illustrates an example that the first type transistor TR1 has a top-gate structure in which the first gate electrode GE1 is disposed over the first semiconductor pattern SP1, embodiments are not limited thereto, and the first type transistor TR1 may have a bottom-gate structure in which the first gate electrode GE1 is disposed under the first semiconductor pattern SP1 in another embodiment.

The third insulating layer 30 may be disposed on the second insulating layer 20. The third insulating layer 30 may cover the first gate electrode GE1.

A scan line SL may be disposed on the third insulating layer 30. The scan line SL may correspond to a part of the above-described first to third scan lines GWi, GCi, and Gli (refer to FIG. 5).

The fourth insulating layer 40 may be disposed on the third insulating layer 30. The fourth insulating layer 40 may cover the scan line SL.

A semiconductor pattern (hereinafter, referred to as the second semiconductor pattern SP2) of the second type transistor TR2 may be disposed on the fourth insulating layer 40. The second semiconductor pattern SP2 may include an oxide semiconductor including metal oxide. The oxide semiconductor may include metal oxide of zinc (Zn), indium (In), gallium (Ga), tin (Sn), or titanium (Ti), or may include metal such as zinc (Zn), indium (In), gallium (Ga), tin (Sn), or titanium (Ti) and a mixture of oxides thereof. The oxide semiconductor may include indium-tin oxide (“ITO”), indium-gallium-zinc oxide (“IGZO”), zinc oxide (ZnO), indium-zinc oxide (“IZO”), zinc-indium oxide (“ZIO”), indium oxide (InO), titanium oxide (TiO), indium-zinc-tin oxide (“IZTO”), or zinc-tin oxide (“ZTO”). However, embodiments are not necessarily limited thereto.

The second semiconductor pattern SP2 may include a plurality of regions having different electrical properties depending on whether metal oxide is reduced or not. A region of the second semiconductor pattern SP2 where metal oxide is reduced (hereinafter, referred to as the reduced region) has a higher conductivity than a region where metal oxide is not reduced (hereinafter, referred to as the non-reduced region). The reduced region may substantially serve as a source or drain of a transistor. The non-reduced region may substantially correspond to an active (or, channel) region of the transistor.

A source region S2, an active region A2, and a drain region D2 of the second type transistor TR2 may be formed from the second semiconductor pattern SP2. The source region S2 and the drain region D2 may extend from the active region A2 in opposite directions in a sectional view.

The fifth insulating layer 50 may be disposed on the fourth insulating layer 40. The fifth insulating layer 50 may cover the second semiconductor pattern SP2.

A gate electrode (hereinafter, referred to as the second gate electrode GE2) of the second type transistor TR2 may be disposed on the fifth insulating layer 50. The second gate electrode GE2 may overlap the active region A2 in a plan view. In an embodiment, the second gate electrode GE2 may function as a mask in a process of doping the second semiconductor pattern SP2.

In an embodiment, the second semiconductor pattern SP2 may overlap a portion of the scan line SL disposed under the second semiconductor pattern SP2 in a plan view. The portion of the scan line SL that overlaps the second semiconductor pattern SP2 in a plan view may serve as a gate of the second type transistor TR2 together with the second gate electrode GE2. In this case, the gate of the second type transistor TR2 may be formed double. Accordingly, the gate of the second type transistor TR2 may have sufficient gate charges and may be switched at high speed. In addition, because the scan line SL overlaps the second semiconductor pattern SP2 in a plan view, the second semiconductor pattern SP2 may be prevented from being damaged by light introduced from below the display panel DP. However, the structure of the second type transistor TR2 is illustrative, and embodiments are not limited thereto.

The second semiconductor pattern SP2 of the second type transistor TR2 and the first semiconductor pattern SP1 of the first type transistor TR1 may be disposed on different layers. However, this is illustrative, and semiconductor patterns of all of the transistors included in the pixel drive circuit PDC (refer to FIG. 5) may be disposed on the same layer.

The sixth insulating layer 60 may be disposed on the fifth insulating layer 50. The sixth insulating layer 60 may cover the second gate electrode GE2.

The connecting electrodes CNE11, CNE12, CNE13, and CNE2 may include the connecting electrodes 1-1 CNE11, 1-2 CNE12, and 1-3 CNE13 and the second connecting electrode CNE2. The connecting electrodes 1-1 CNE11, 1-2 CNE12, and 1-3 CNE13 may be disposed on the sixth insulating layer 60. The connecting electrodes 1-1 CNE11, 1-2 CNE12, and 1-3 CNE13 may be disposed on the sixth insulating layer 60 so as to be spaced apart from each other in a plan view. In FIG. 6, for convenience, the connecting electrodes CNE11, CNE12, and CNE13 are illustrated as overlapping entireties of contact holes CNT-11, CNT-12a, CNT-12b, and CNT-13 in a plan view and having flat upper surfaces. However, the connecting electrodes CNE11, CNE12, and CNE13 of an embodiment may be disposed along inner surfaces of the contact holes CNT-11, CNT-12a, CNT-12b, and CNT-13 and may not overlap central portions of the contact holes CNT-11, CNT-12a, CNT-12b, and CNT-13 in a plan view. In this embodiment, auxiliary electrodes may be additionally disposed in at least some of the contact holes CNT-11, CNT-12a, CNT-12b, and CNT-13, and detailed description thereabout will be given below.

The connecting electrode 1-1 CNE11 may be connected to the drain region D1 of the first type transistor TR1. The connecting electrode 1-1 CNE11 may be connected to the drain region D1 through the contact hole CNT-11 penetrating the second to sixth insulating layers 20 to 60.

The connecting electrode 1-2 CNE12 may be connected to the first source region S1 of the first type transistor TR1. The connecting electrode 1-2 CNE12 may be connected to the first source region S1 through the contact hole CNT-12a penetrating the second to sixth insulating layers 20 to 60.

The connecting electrode 1-2 CNE12 may extend and may overlap the drain region D2 of the second type transistor TR2 in a plan view. The connecting electrode 1-2 CNE12 may be connected to the drain region D2 through the contact hole CNT-12b penetrating the fifth and sixth insulating layers 50 and 60. Accordingly, the second semiconductor pattern SP2 of the second type transistor TR2 and the first semiconductor pattern SP1 of the first type transistor TR1 disposed on different layers may be electrically connected with each other through the connecting electrode 1-2 CNE12.

The connecting electrode 1-3 CNE13 may be connected to the second source region S2 of the second type transistor TR2. The connecting electrode 1-3 CNE13 may be connected to the second source region S2 through the contact hole CNT-13 penetrating the fifth and sixth insulating layers 50 and 60.

The seventh insulating layer 70 may be disposed on the sixth insulating layer 60. The seventh insulating layer 70 may cover the connecting electrodes 1-1 CNE11, 1-2 CNE12, and 1-3 CNE13.

The second connecting electrode CNE2 may be disposed on the seventh insulating layer 70. In addition, although not separately illustrated, some of the signal lines included in the display panel DP may be disposed on the seventh insulating layer 70.

The second connecting electrode CNE2 may be connected to the connecting electrode 1-1 CNE11 through a contact hole CNT-2 penetrating the seventh insulating layer 70. The second connecting electrode CNE2 may be connected to the drain region D1 of the first type transistor TR1 through the connecting electrode 1-1 CNE11. In an embodiment, the first type transistor TR1 illustrated in FIG. 6 may correspond to the sixth transistor T6 that is connected to the first electrode AE in FIG. 5. However, embodiments are not limited thereto, and the second connecting electrode CNE2 may be omitted, or an additional connecting electrode disposed between the second connecting electrode CNE2 and the connecting electrode 1-1 CNE11 may be further disposed in the circuit layer DP-CL in another embodiment.

The eighth insulating layer 80 may be disposed on the seventh insulating layer 70. The eighth insulating layer 80 may cover the second connecting electrode CNE2.

At least one of the seventh insulating layer 70 and the eighth insulating layer 80 may include an organic layer. The organic layer may provide a flat surface while covering particles existing on a surface of a layer disposed under the organic layer or covering steps between components disposed under the organic layer. In addition, the organic layer may alleviate stress between components disposed on and under the organic layer.

The display element layer DP-OLED may be disposed on the circuit layer DP-CL. The display element layer DP-OLED may include a pixel defining layer PDL and the light emitting element OLED. The light emitting element OLED may include the first electrode AE, an emissive layer EML, and the second electrode CE.

The light emitting element OLED may include an organic light emitting element, a quantum-dot light emitting element, a micro LED light emitting element, or a nano LED light emitting element. However, embodiments are not limited thereto, and the light emitting element OLED may include various embodiments as long as light is generated, or the amount of light is controlled, depending on an electrical signal.

The light emitting element OLED may be electrically connected to the transistors of the corresponding pixel drive circuit PDC (refer to FIG. 5). FIG. 6 illustrates an example that the light emitting element OLED is electrically connected to a corresponding transistor (e.g., the sixth transistor T6 of FIG. 5).

The first electrode AE of the light emitting element OLED may be disposed in the uppermost layer of the circuit layer DP-CL. In an embodiment, for example, the first electrode AE may be disposed on the eighth insulating layer 80. The first electrode AE may be connected to the corresponding second connecting electrode CNE2 through a contact hole CNT-U penetrating the eighth insulating layer 80. The first electrode AE may be electrically connected to the first type transistor TR1 through the second connecting electrode CNE2 and the connecting electrode 1-1 CNE11.

The pixel defining layer PDL may be disposed in the uppermost layer of the circuit layer DP-CL. In an embodiment, for example, the pixel defining layer PDL may be disposed on the eighth insulating layer 80. A light emitting opening PX-OP for exposing a portion of the first electrode AE may be defined in the pixel defining layer PDL. The display region DA (refer to FIG. 4) of the display panel DP may include an emissive region PXA and a non-emissive region NPXA. In this embodiment, the region of the first electrode AE exposed by the light emitting opening PX-OP may correspond to the emissive region PXA. The region in which the pixel defining layer PDL is disposed may correspond to the non-emissive region NPXA. In a plan view, the non-emissive region NPXA may surround the emissive region PXA and may set the boundary of the emissive region PXA.

The pixel defining layer PDL may include a polymer resin. In an embodiment, for example, the pixel defining layer PDL may include a polyacrylate-based resin or a polyimide-based resin. However, without being limited thereto, the pixel defining layer PDL may further include an inorganic material.

The pixel defining layer PDL may further include a light absorbing material. In an embodiment, for example, the pixel defining layer PDL may include a black coloring agent such as a black dye or a black pigment. In an embodiment, for example, the black coloring agent may include carbon black, metal such as chromium, or oxide thereof. However, embodiments are not necessarily limited thereto.

The emissive layer EM may be disposed on the first electrode AE. The emissive layer EM of the light emitting element OLED may be disposed to correspond to the light emitting opening PX-OP and may be formed in an emission pattern spaced apart from a plurality of light emitting elements in a plan view. However, without being limited thereto, the emissive layer EM may be formed of an integrated film and may function as a common layer for the plurality of light emitting elements. The emissive layer EM may include an organic luminescent material and/or an inorganic luminescent material. In an embodiment, for example, the emissive layer EM may include a fluorescent material, a phosphorescent material, a metal organic complex luminescent material, or quantum dots. The emissive layer EM may emit one of red light, green light, and blue light.

The second electrode CE may be disposed on the emissive layer EM. The second electrode CE may overlap the emissive region PXA and the non-emissive region NPXA. The second electrode CE may be commonly disposed for the plurality of pixels PX (refer to FIG. 4) and may provide a common voltage to the plurality of pixels PX (refer to FIG. 4).

The light emitting element OLED may further include an emission control layer disposed between the first electrode AE and the second electrode CE. In an embodiment, for example, the emission control layer may include a hole control layer disposed between the first electrode AE and the emissive layer EM and an electron control layer disposed between the emissive layer EM and the second electrode CE. The hole control layer may include a hole injection layer, a hole transport layer, or an electron blocking layer, and the electron control layer may include an electron injection layer, an electron transport layer, or a hole blocking layer.

The thin film encapsulation layer TFE may be disposed on the display element layer DP-OLED. The thin film encapsulation layer TFE may seal the light emitting element OLED. The thin film encapsulation layer TFE may include at least one of an inorganic film and an organic film. In an embodiment, the thin film encapsulation layer TFE may include inorganic films and an organic film disposed between the inorganic films.

The inorganic film of the thin film encapsulation layer TFE may protect the light emitting element OLED from moisture and/or oxygen. The inorganic film may include at least one of aluminum oxide, titanium oxide, silicon oxide, silicon nitride, silicon oxy nitride, zirconium oxide, and hafnium oxide. However, the material of the inorganic film is not limited thereto.

The organic film of the thin film encapsulation layer TFE may protect the light emitting element OLED from foreign matter such as dust particles. The organic film may include an acrylic resin. However, the material of the organic film is not limited thereto.

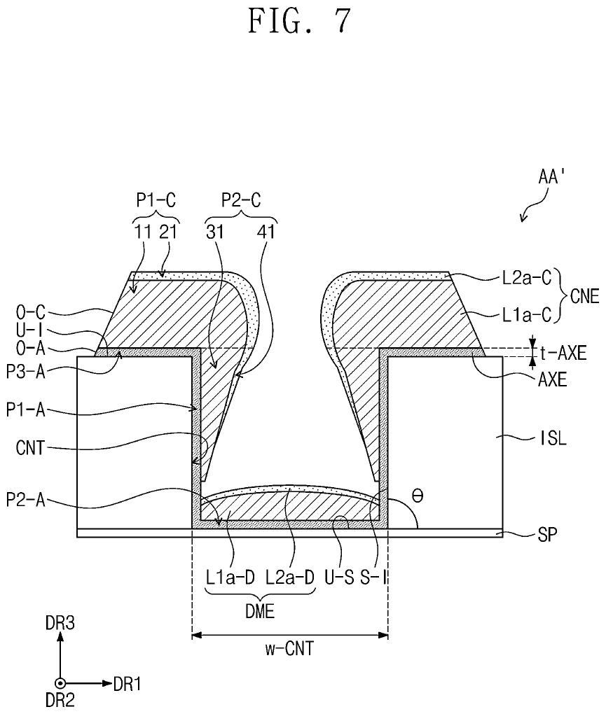

FIG. 7 is a sectional view of a partial configuration of the display device according to an embodiment of the present disclosure. FIG. 7 is an enlarged view of region AA′ illustrated in FIG. 6, and FIG. 7 illustrates a section within the circuit layer DP-CL (refer to FIG. 6). In FIG. 7, a contact hole CNT penetrating an insulating layer ISL within the circuit layer DP-CL (refer to FIG. 6) is illustrated. In describing FIG. 7, components identical or similar to the components described with reference to FIGS. 1A to 6 will be assigned with identical or similar reference numerals, and repetitive descriptions will be omitted.

Referring to FIG. 7, the contact hole CNT according to this embodiment may expose a portion of a semiconductor pattern SP. The semiconductor pattern SP of FIG. 7 may be the first semiconductor pattern SP1 of the first type transistor TR1 in FIG. 6 or the second semiconductor pattern SP2 of the second type transistor TR2 in FIG. 6.

When the semiconductor pattern SP of FIG. 7 corresponds to the first semiconductor pattern SP1 of FIG. 6, the insulating layer ISL of FIG. 7 may correspond to the second to sixth insulating layers 20 to 60 of FIG. 6. The contact hole CNT of FIG. 7 may be a contact hole (e.g., the contact holes CNT-11 and CNT-12a of FIG. 6) defined to penetrate the second to sixth insulating layers 20 to 60 in FIG. 6.

When the semiconductor pattern SP of FIG. 7 corresponds to the second semiconductor pattern SP2 of FIG. 6, the insulating layer ISL of FIG. 7 may correspond to the fifth and sixth insulating layers 50 and 60 of FIG. 6. The contact hole CNT of FIG. 7 may be a contact hole (e.g., the contact holes CNT-12b and CNT-13 of FIG. 6) defined to penetrate the fifth and sixth insulating layers 50 and 60 in FIG. 6.

In this specification, the contact hole CNT may include a sidewall and a bottom surface. The sidewall of the contact hole CNT may correspond to an inner surface S-I of the insulating layer ISL that defines the contact hole CNT, and the bottom surface of the contact hole CNT may correspond to an upper surface U-S of the semiconductor pattern SP exposed from the insulating layer ISL.

The slope of the inner surface S-I of the insulating layer ISL (or, the sidewall of the contact hole CNT) that defines the contact hole CNT may be substantially vertical. In an embodiment, the inner surface S-I of the insulating layer ISL may have a slope of 80 degrees to 90 degrees. The “slope” of the inner surface S-I of the insulating layer ISL may be defined as an angle θ formed by the inner surface S-I of the insulating layer ISL with respect to the upper surface U-S of the semiconductor pattern SP. Because the slope of the inner surface S-I of the insulating layer ISL is substantially vertical, a difference in width between an upper side and a lower side of the contact hole CNT may be minimized. Accordingly, a reduction in an exposed area of the semiconductor pattern SP may be minimized in a process of reducing the size of the contact hole CNT, and high resolution may be more easily implemented.

In an embodiment, the contact hole CNT may have a width w-CNT of 2.0 micrometers or less. In an embodiment, for example, the contact hole CNT may have a width w-CNT of 1.0 micrometer to 2.0 micrometers. The “width w-CNT” of the contact hole CNT may be defined as a maximum width of the contact hole CNT in a direction perpendicular to the third direction DR3 (e.g., first direction DR1). In an embodiment, the contact hole CNT may have a circular shape in a plan view, and the width w-CNT of the contact hole CNT may correspond to a maximum diameter of the contact hole CNT in a plan view.

The display panel DP (refer to FIG. 6) according to the present disclosure may further include an auxiliary electrode AXE at least partially disposed in the contact hole CNT. The auxiliary electrode AXE according to this embodiment may include a first auxiliary portion P1-A, a second auxiliary portion P2-A, and a third auxiliary portion P3-A.

The first auxiliary portion P1-A may be a portion making contact with the inner surface S-I of the insulating layer ISL that defines the contact hole CNT. The first auxiliary portion P1-A may cover the entirety of the inner surface S-I of the insulating layer ISL (or, the sidewall of the contact hole CNT) that defines the contact hole CNT. The second auxiliary portion P2-A may be a portion making contact with the semiconductor pattern SP exposed from the insulating layer ISL by the contact hole CNT. The second auxiliary portion P2-A may cover the entirety of the upper surface U-S of the semiconductor pattern SP (or, the bottom surface of the contact hole CNT) exposed from the insulating layer ISL. The third auxiliary portion P3-A may be a portion making contact with a portion of an upper surface U-I of the insulating layer ISL.

In this specification, for convenience of description, the first to third auxiliary portions P1-A, P2-A, and P3-A are defined by dividing the region of the auxiliary electrode AXE. The first to third auxiliary portions P1-A, P2-A, and P3-A form substantially one component.

In an embodiment, the auxiliary electrode AXE may include tungsten (W). The tungsten may have excellent step coverage. The tungsten may be easily deposited by a deposition process (e.g., a chemical vapor deposition (“CVD”) process) capable of providing excellent step coverage characteristics. Accordingly, even though the inner surface S-I of the insulating layer ISL that defines the contact hole CNT has a substantially vertical slope, the auxiliary electrode AXE may cover the entirety of the inner surface S-I of the insulating layer ISL (or, the sidewall of the contact hole CNT), and the first auxiliary portion P1-A and the second auxiliary portion P2-A may not be separated.

The auxiliary electrode AXE may be deposited in the form of a thin film and may cover the sidewall and the bottom surface of the contact hole CNT. In an embodiment, the auxiliary electrode AXE may have a thickness t-AXE of 100 Å to 500 Å. When the auxiliary electrode AXE has a thickness t-AXE of less than 100 Å, electrical connection with the semiconductor pattern SP and a connecting electrode CNE may not be stable. The auxiliary electrode AXE according to an embodiment may include a material having a higher electrical resistance than the connecting electrode CNE. When the auxiliary electrode AXE has a thickness t-AXE of more than 500 Å, the total resistance of electrodes electrically connected to the semiconductor pattern SP may be increased, and therefore power consumption may be increased.

The connecting electrode CNE may include a first connecting portion P1-C and a second connecting portion P2-C.

The first connecting portion P1-C may be a portion disposed on the insulating layer ISL. The first connecting portion P1-C may make contact with the third auxiliary portion P3-A of the auxiliary electrode AXE. The first connecting portion P1-C may cover the entirety of the third auxiliary portion P3-A. A portion of the first connecting portion P1-C may overlap a portion of the contact hole CNT in a plan view.

The second connecting portion P2-C may be a portion that extends downward from the first connecting portion P1-C and that is disposed in the contact hole CNT. The second connecting portion P2-C may make contact with the first auxiliary portion P1-A of the auxiliary electrode AXE. The second connecting portion P2-C may cover only one portion of the first auxiliary portion P1-A. That is, the other portion of the first auxiliary portion P1-A may be exposed without being covered by the connecting electrode CNE. The second connecting portion P2-C may have a decreasing thickness as the second connecting portion P2-C extends downward.

In this specification, for convenience of description, the first and second connecting portions P1-C and P2-C are defined by dividing the region of the connecting electrode CNE. The first and second connecting portions P1-C and P2-C form substantially one component.

The connecting electrode CNE may overlap an outer portion of the contact hole CNT, but may not overlap an inner portion of the contact hole CNT in a plan view. The “outer portion” of the contact hole CNT may refer to a portion adjacent to the sidewall of the contact hole CNT, and the “inner portion” of the contact hole CNT may refer to a portion adjacent to the center of the contact hole CNT.

In this embodiment, the connecting electrode CNE may include a 1-1st connecting electrode layer L1a-C and a 2-1st connecting electrode layer L2a-C. The 1-1st connecting electrode layer L1a-C may be directly disposed on the first and third auxiliary portions P1-A and P3-A of the auxiliary electrode AXE. The 2-1st connecting electrode layer L2a-C may be directly disposed on the 1-1st connecting electrode layer L1a-C.

In this embodiment, the first connecting portion P1-C may include a portion of the 1-1st connecting electrode layer L1a-C (hereinafter, referred to as the 1-1st sub-portion 11) disposed on the insulating layer ISL and a portion of the 2-1st connecting electrode layer L2a-C (hereinafter, referred to as the 2-1st sub-portion 21) disposed on the insulating layer ISL. The second connecting portion P2-C may include a portion of the 1-1st connecting electrode layer L1a-C (hereinafter, referred to as the sub-portion 3-1 31) disposed in the contact hole CNT and a portion of the 2-1st connecting electrode layer L2a-C (hereinafter, referred to as the sub-portion 4-1 41) disposed in the contact hole CNT.

The 1-1st connecting electrode layer L1a-C may have a greater average thickness than the 2-1st connecting electrode layer L2a-C. The 1-1st connecting electrode layer L1a-C may have a greater average thickness than the auxiliary electrode AXE. In this specification, in the first connecting portion P1-C, the thickness of the connecting electrode CNE may refer to a thickness in the third direction DR3, and in the second connecting portion P2-C, the thickness of the connecting electrode CNE may refer to a thickness in a direction parallel to a plane defined by the first and second directions DR1 and DR2. In the second and third auxiliary portions P2-A and P3-A, the thickness of the auxiliary electrode AXE may refer to a thickness in the third direction DR3, and in the first auxiliary portion P1-A, the thickness of the auxiliary electrode AXE may refer to a thickness in the direction parallel to the plane defined by the first and second directions DR1 and DR2.

Each of the 1-1st and 2-1st connecting electrode layers L1a-C and L2a-C may include a conductive material. The 1-1st connecting electrode layer L1a-C may include a first conductive material, and the 2-1st connecting electrode layer L2a-C may include a second conductive material different from the first conductive material. In an embodiment, the first conductive material may have a higher electrical conductivity than the second conductive material. Furthermore, in an embodiment, the first conductive material may have a lower electrical resistance than the second conductive material. In an embodiment, for example, the 1-1st connecting electrode layer L1a-C may include aluminum (Al), and the 2-1st connecting electrode layer L2a-C may include titanium (Ti).

The circuit layer DP-CL (refer to FIG. 6) according to this embodiment may further include a dummy electrode DME disposed in the contact hole CNT. The dummy electrode DME may be directly disposed on the second auxiliary portion P2-A of the auxiliary electrode AXE in the contact hole CNT. The dummy electrode DME may cover the entirety of the second auxiliary portion P2-A.

In this embodiment, the dummy electrode DME may include a 1-1st dummy electrode layer L1a-D and a 2-1st dummy electrode layer L2a-D. The 1-1st dummy electrode layer L1a-D may be directly disposed on the second auxiliary portion P2-A, and the 2-1st dummy electrode layer L2a-D may be directly disposed on the 1-1 st dummy electrode layer L1a-D.

The dummy electrode DME may be spaced apart from the connecting electrode CNE. The dummy electrode DME may be simultaneously formed together with the connecting electrode CNE in a process of forming the connecting electrode CNE. The dummy electrode DME may be separated from the connecting electrode CNE. The dummy electrode DME may be disposed at least in the inner portion of the contact hole CNT, which does not overlap the connecting electrode CNE in a plan view.

The 1-1st dummy electrode layer L1a-D may be formed to be separated from the 1-1st connecting electrode layer L1a-C. The 1-1st dummy electrode layer L1a-D may include the same material as the 1-1st connecting electrode layer L1a-C. The 2-1st dummy electrode layer L2a-D may be formed to be separated from the 2-1st connecting electrode layer L2a-C. The 2-1st dummy electrode layer L2a-D may include the same material as the 2-1st connecting electrode layer L2a-C. In an embodiment, the 1-1st dummy electrode layer L1a-D may include aluminum, and the 2-1st dummy electrode layer L2a-D may include titanium.

When the contact hole CNT has a small size and the slope of the sidewall of the contact hole CNT is substantially vertical, the connecting electrode CNE may overhang, and thus a shadow effect may occur. In a deposition process for forming the connecting electrode CNE, a deposition material may fail to reach an end portion of the lower side (i.e., bottom) of the contact hole CNT. Accordingly, in the process of forming the connecting electrode CNE, the dummy electrode DME separated from the connecting electrode CNE may be formed together.

According to this embodiment, by providing the auxiliary electrode AXE that includes portions making contact with the connecting electrode CNE (that is, the first and third auxiliary portions P1-A and P3-A) and a portion making contact with the upper surface U-S of the semiconductor pattern SP (that is, the second auxiliary portion P2-A), the connecting electrode CNE may be electrically connected to the semiconductor pattern SP through the auxiliary electrode AXE. Accordingly, even though the connecting electrode CNE covers only a portion of the sidewall of the contact hole CNT and has a shape disconnected from the semiconductor pattern SP in the contact hole CNT, a defect in connection of the connecting electrode CNE may be effectively prevented through the auxiliary electrode AXE.

In this embodiment, the auxiliary electrode AXE may make direct contact with the semiconductor pattern SP. In an embodiment, the auxiliary electrode AXE may include tungsten, and the semiconductor pattern SP may include poly-silicon. The tungsten may form a stable ohmic contact with the poly-silicon. Accordingly, the auxiliary electrode AXE and the semiconductor pattern SP may secure stable contact characteristics, and thus the pixel drive circuit PDC (refer to FIG. 5) with stable electrical characteristics and the display device DD (refer to FIG. 1) including the same may be provided.

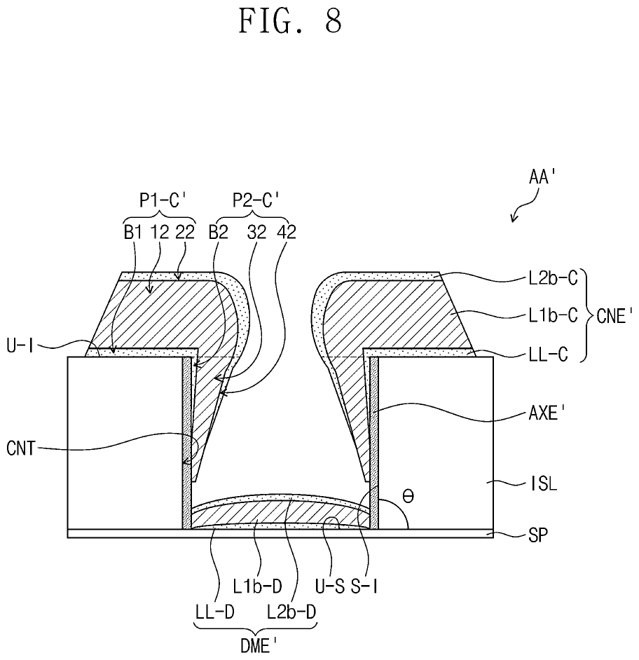

FIG. 8 is a sectional view of a partial configuration of the display device according to an embodiment of the present disclosure. FIG. 8 is an enlarged view of region AA′ illustrated in FIG. 6, where FIG. 8 illustrates a section within the circuit layer DP-CL (refer to FIG. 6). In FIG. 8, the contact hole CNT penetrating the insulating layer ISL within the circuit layer DP-CL (refer to FIG. 6) is illustrated. In describing FIG. 8, components identical or similar to the components described with reference to FIGS. 1A to 7 will be assigned with identical or similar reference numerals, and repetitive descriptions will be omitted.

Referring to FIG. 8, an auxiliary electrode AXE′ according to this embodiment may all be disposed in the contact hole CNT. The auxiliary electrode AXE′ may make contact with the inner surface S-I of the insulating layer ISL that defines the contact hole CNT. The auxiliary electrode AXE′ may cover the entirety of the inner surface S-I of the insulating layer ISL (or, the sidewall of the contact hole CNT) that defines the contact hole CNT. Meanwhile, the auxiliary electrode AXE′ according to this embodiment may be provided in the form of a thin film that covers only the inner surface S-I of the insulating layer ISL. A lower edge of the auxiliary electrode AXE′ may make contact with the semiconductor pattern SP. The upper surface U-S of the semiconductor pattern SP may be exposed by the auxiliary electrode AXE′. In addition, the auxiliary electrode AXE′ according to this embodiment may not cover the upper surface U-I of the insulating layer ISL. That is, the auxiliary electrode AXE′ in FIG. 8 may include only the first auxiliary portion P1-A of the auxiliary electrode AXE in FIG. 7.

In an embodiment, the auxiliary electrode AXE′ may include tungsten (W). The tungsten may have excellent step coverage. The tungsten may be easily deposited by a deposition process (e.g., a chemical vapor deposition (CVD) process) capable of providing excellent step coverage characteristics. Accordingly, even though the inner surface S-I of the insulating layer ISL that defines the contact hole CNT has a substantially vertical slope, the auxiliary electrode AXE′ may cover the entirety of the inner surface S-I of the insulating layer ISL (or, the sidewall of the contact hole CNT).

A connecting electrode CNE′ may include a first connecting portion P1-C′ disposed on the insulating layer ISL and a second connecting portion P2-C′ disposed in the contact hole CNT. The first connecting portion PI-C′ may make contact with a portion of the upper surface U-I of the insulating layer ISL. The second connecting portion P2-C′ may make contact with the auxiliary electrode AXE′. The second connecting portion P2-C′ may cover only a portion of the auxiliary electrode AXE′.

In this specification, for convenience of description, the first and second connecting portions P1-C′ and P2-C′ are defined by dividing the region of the connecting electrode CNE′. The first and second connecting portions P1-C′ and P2-C′ form substantially one component.

In this embodiment, the connecting electrode CNE′ may include a lower connecting electrode layer LL-C, a 1-2nd connecting electrode layer L1b-C, and a 2-2nd connecting electrode layer L2b-C. A portion of the lower connecting electrode layer LL-C included in the first connecting portion P1-C′ may be directly disposed on the upper surface U-I of the insulating layer ISL, and a portion of the lower connecting electrode layer LL-C included in the second connecting portion P2-C′ may make contact with a portion of the auxiliary electrode AXE′ and may cover the portion of the auxiliary electrode AXE′. The 1-2nd connecting electrode layer L1b-C may be directly disposed on the lower connecting electrode layer LL-C, and the 2-2nd connecting electrode layer L2b-C may be directly disposed on the 1-2nd connecting electrode layer L1b-C.

In this embodiment, the first connecting portion P1-C′ may include a portion of the lower connecting electrode layer LL-C disposed on the insulating layer ISL (hereinafter, referred to as the first lower sub-portion B1), a portion of the 1-2nd connecting electrode layer L1b-C disposed on the insulating layer ISL (hereinafter, referred to as the 1-2nd sub-portion 12), and a portion of the 2-2nd connecting electrode layer L2b-C disposed on the insulating layer ISL (hereinafter, referred to as the 2-2nd sub-portion 22). The second connecting portion P2-C′ may include a portion of the lower connecting electrode layer LL-C disposed in the contact hole CNT (hereinafter, referred to as the second lower sub-portion B2), a portion of the 1-2nd connecting electrode layer L1b-C disposed in the contact hole CNT (hereinafter, referred to as the 3-2nd sub-portion 32), and a portion of the 2-2nd connecting electrode layer L2b-C disposed in the contact hole CNT (hereinafter, referred to as the 4-2nd sub-portion 42).

The 1-2nd connecting electrode layer L1b-C may have a greater average thickness than the lower connecting electrode layer LL-C and the 2-2nd connecting electrode layer L2b-C. The 1-2nd connecting electrode layer L1b-C may have a greater average thickness than the auxiliary electrode AXE′.

Each of the lower connecting electrode layer LL-C, the 1-2nd connecting electrode layer L1b-C, and the 2-2nd connecting electrode layer L2b-C may include a conductive material. The 1-2nd connecting electrode layer L1b-C may include a first conductive material, and the lower connecting electrode layer LL-C and the 2-2nd connecting electrode layer L2b-C may include a second conductive material different from the first conductive material. The lower connecting electrode layer LL-C may include the same material as the 2-2nd connecting electrode layer L2b-C. In an embodiment, the first conductive material may have a higher electrical conductivity than the second conductive material. Furthermore, in an embodiment, the first conductive material may have a lower electrical resistance than the second conductive material. In an embodiment, for example, the 1-2nd connecting electrode layer L1b-C may include aluminum, and each of the lower connecting electrode layer LL-C and the 2-2nd connecting electrode layer L2b-C may include titanium.

A dummy electrode DME′ may be directly disposed on the upper surface U-S of the semiconductor pattern SP exposed from the insulating layer ISL and the auxiliary electrode AXE′ in the contact hole CNT. The dummy electrode DME′ may cover the entirety of the exposed upper surface U-S of the semiconductor pattern SP. An edge of the dummy electrode DME′ disposed adjacent to the sidewall of the contact hole CNT may make contact with the auxiliary electrode AXE′.

The dummy electrode DME′ may include a lower dummy electrode layer LL-D, a 1-2nd dummy electrode layer L1b-D, and a 2-2nd dummy electrode layer L2b-D. The lower dummy electrode layer LL-D may be directly disposed on the upper surface U-S of the semiconductor pattern SP, the 1-2nd dummy electrode layer Lib-D may be directly disposed on the lower dummy electrode layer LL-D, and the 2-2nd dummy electrode layer L2b-D may be directly disposed on the 1-2nd dummy electrode layer L1b-D.

The lower dummy electrode layer LL-D may be formed to be separated from the lower connecting electrode layer LL-C, the 1-2nd dummy electrode layer L1b-D may be formed to be separated from the 1-2nd connecting electrode layer L1b-C, and the 2-2nd dummy electrode layer L2b-D may be formed to be separated from the 2-2nd connecting electrode layer L2b-C. The lower dummy electrode layer LL-D may include the same material as the lower connecting electrode layer LL-C, the 1-2nd dummy electrode layer L1b-D may include the same material as the 1-2nd connecting electrode layer L1b-C, and the 2-2nd dummy electrode layer L2b-D may include the same material as the 2-2nd connecting electrode layer L2b-C. In an embodiment, the 1-2nd dummy electrode layer L1b-D may include aluminum, and each of the lower dummy electrode layer LL-D and the 2-2nd dummy electrode layer L2b-D may include titanium.

According to this embodiment, the dummy electrode DME′ may make direct contact with the semiconductor pattern SP. However, by providing the auxiliary electrode AXE′ including a portion making contact with the dummy electrode DME′ and a portion making contact with the connecting electrode CNE′, the connecting electrode CNE′ may be electrically connected to the semiconductor pattern SP through the auxiliary electrode AXE′ and the dummy electrode DME′. Accordingly, even though a shadow effect occurs and the connecting electrode CNE′ covers only a portion of the sidewall of the contact hole CNT and has a shape disconnected from the semiconductor pattern SP in the contact hole CNT, a defect in connection of the connecting electrode CNE′ may be effectively prevented through the auxiliary electrode AXE′.

In this embodiment, the dummy electrode DME′ may make direct contact with the semiconductor pattern SP. In an embodiment, the lower dummy electrode layer LL-D of the dummy electrode DME′ may include titanium, and the semiconductor pattern SP may include poly-silicon. The titanium may form a stable ohmic contact with the poly-silicon. Accordingly, the dummy electrode DME′ and the semiconductor pattern SP may secure stable contact characteristics, and thus the pixel drive circuit PDC (refer to FIG. 5) with stable electrical characteristics and the display device DD (refer to FIG. 1) including the same may be provided.

Although the connection forms between the semiconductor pattern SP and the electrode in the contact hole CNT exposing the semiconductor pattern SP have been described with reference to FIGS. 7 and 8, embodiments are not necessarily limited thereto, and other contact holes exposing other electrodes or electrode layers having conductivity may have the structure including the above-described connection form in the contact hole CNT, which has been described above with reference to FIG. 7 or 8.

Hereinafter, display device manufacturing methods according to embodiments will be described with reference to the accompanying drawings. In describing the display device manufacturing methods according to the embodiments, repetitive descriptions identical to the descriptions of the display device will be omitted.

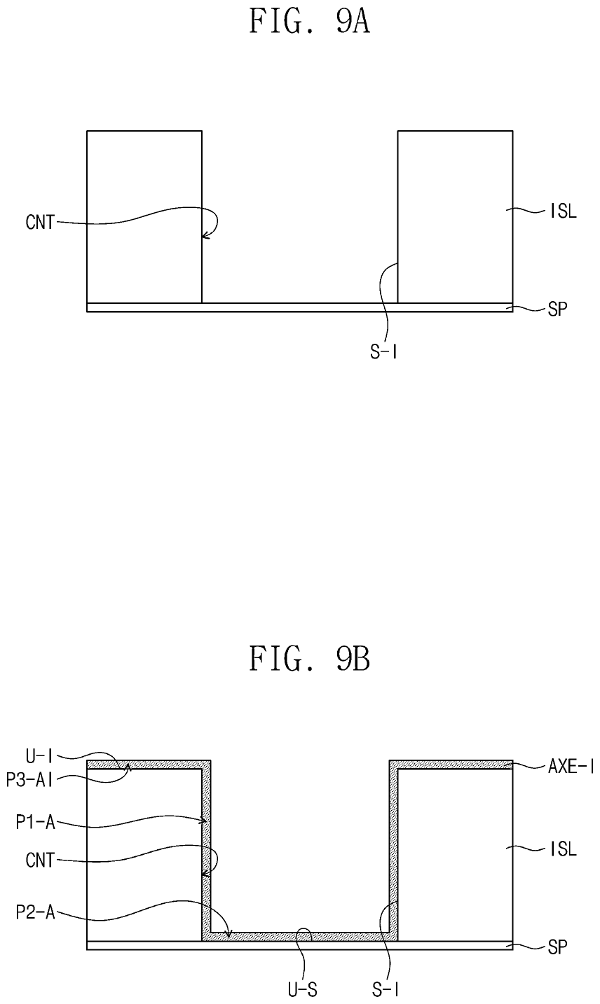

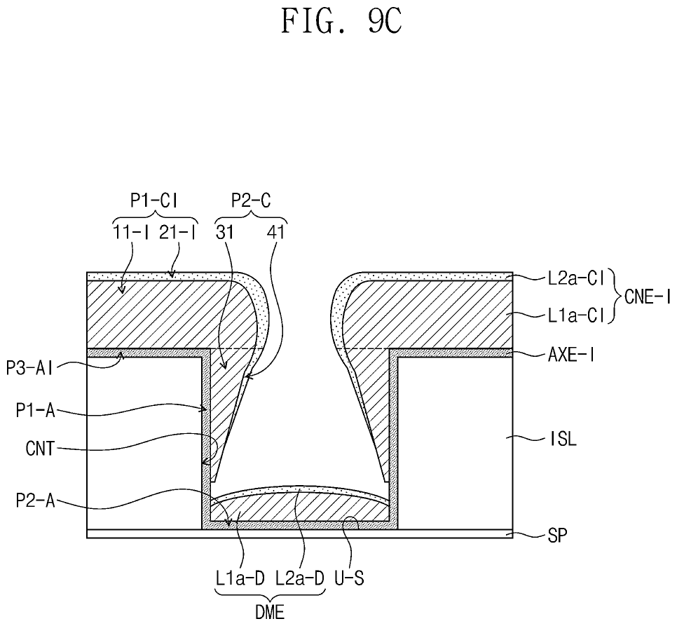

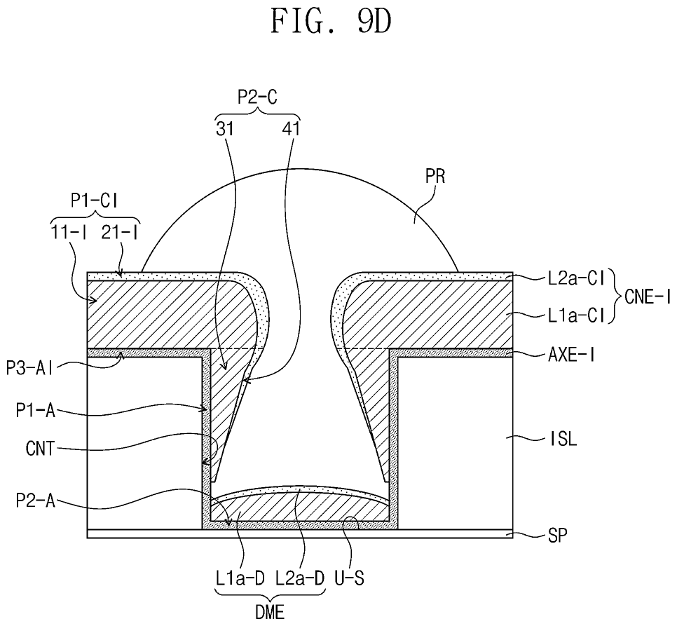

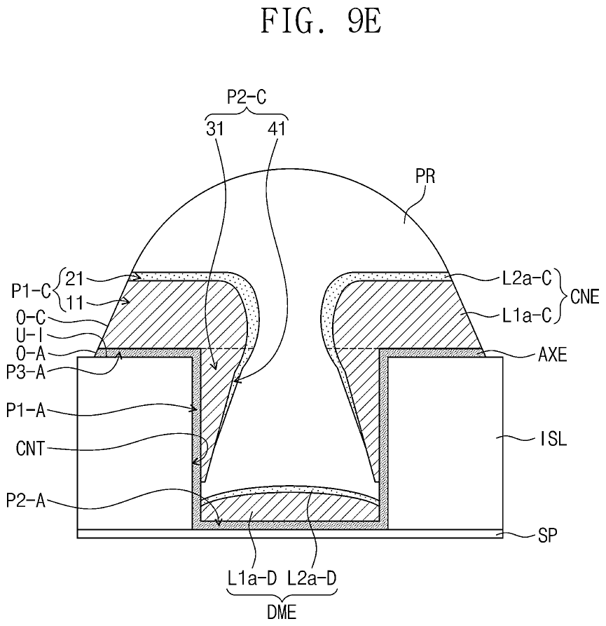

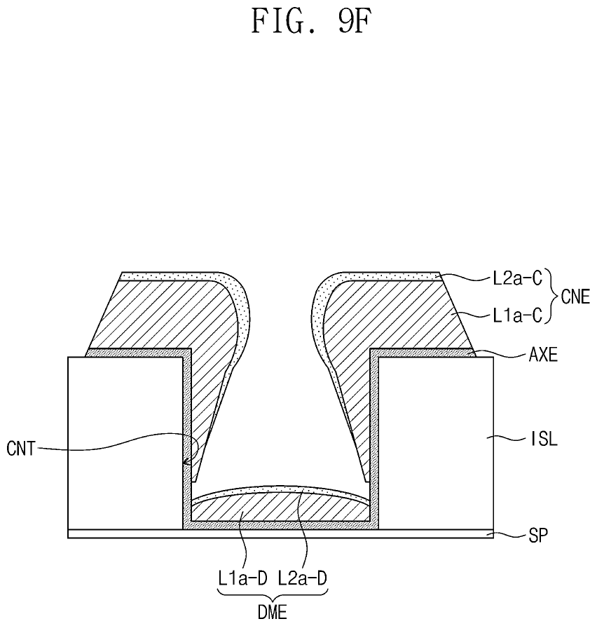

FIGS. 9A to 9F are sectional views illustrating some of the steps of a display device manufacturing method according to an embodiment of the present disclosure.

The display device manufacturing method according to this embodiment may include a step of providing a semiconductor pattern and an insulating layer defining a contact hole therein to expose a portion of the semiconductor pattern, a step of forming a preliminary auxiliary electrode on the insulating layer, a step of forming a preliminary connecting electrode on the insulating layer, a step of etching the preliminary connecting electrode to form a connecting electrode partially disposed in the contact hole, and a step of etching the preliminary auxiliary electrode to form an auxiliary electrode at least partially disposed in the contact hole. The auxiliary electrode may make contact with the connecting electrode and the semiconductor pattern, and the connecting electrode may not overlap a portion (e.g., inner portion) of the contact hole in a plan view.

Referring to FIG. 9A, the display device manufacturing method according to this embodiment may include the step of providing the insulating layer ISL defining the contact hole CNT therein.

The insulating layer ISL may be a component that covers a portion of the semiconductor pattern SP. The semiconductor pattern SP may be provided in a state in which a portion of the semiconductor pattern SP is exposed from the insulating layer ISL by the contact hole CNT.

The inner surface S-I of the insulating layer ISL (or, the sidewall of the contact hole CNT) that defines the contact hole CNT may have a substantially vertical slope. In an embodiment, the inner surface S-I of the insulating layer ISL that defines the contact hole CNT may have a slope of 80 degrees to 90 degrees.

Referring to FIG. 9B, the display device manufacturing method according to this embodiment may include the step of forming the preliminary auxiliary electrode AXE-I. The preliminary auxiliary electrode AXE-I may be formed on the insulating layer ISL.

The preliminary auxiliary electrode AXE-I may be formed through a deposition process. In an embodiment, the deposition process of the preliminary auxiliary electrode AXE-I may be performed through a chemical vapor deposition (CVD) process. The chemical vapor deposition process may provide excellent step coverage characteristics. Accordingly, the preliminary auxiliary electrode AXE-I may be deposited to cover all of the upper surface U-I of the insulating layer ISL, the inner surface S-I of the insulating layer ISL that defines the contact hole CNT, and the exposed upper surface U-S of the semiconductor pattern SP. That is, the preliminary auxiliary electrode AXE-I may be deposited to cover both the sidewall and the bottom surface of the contact hole CNT.

In an embodiment, the preliminary auxiliary electrode AXE-I may include tungsten (W). The tungsten may be a material capable of being easily deposited through the chemical vapor deposition process. Accordingly, the preliminary auxiliary electrode AXE-I may be easily formed through the chemical vapor deposition process and may have excellent step coverage.

The preliminary auxiliary electrode AXE-I may include the first auxiliary portion P1-A, the second auxiliary portion P2-A, and a third preliminary auxiliary portion P3-AI. The first auxiliary portion P1-A may cover the entirety of the inner surface S-I of the insulating layer ISL (or, the sidewall of the contact hole CNT) that defines the contact hole CNT. The second auxiliary portion P2-A may cover the entirety of the upper surface U-S of the semiconductor pattern SP (or, the bottom surface of the contact hole CNT) exposed from the insulating layer ISL. The third preliminary auxiliary portion P3-AI may cover the entirety of the upper surface U-I of the insulating layer ISL.

Referring to FIG. 9C, the display device manufacturing method according to this embodiment may include the step of forming the preliminary connecting electrode CNE-I. The preliminary connecting electrode CNE-I may be formed on the preliminary auxiliary electrode AXE-I.

In this embodiment, the step of forming the preliminary connecting electrode CNE-I may include a step of forming a 1-1st preliminary connecting electrode layer L1a-CI (or, a 1-1st conductive layer) and a step of forming a 2-1st preliminary connecting electrode layer L2a-CI (or, a 2-1st conductive layer). The 1-1st preliminary connecting electrode layer L1a-CI may be formed on the preliminary auxiliary electrode AXE-I, and the 2-1st preliminary connecting electrode layer L2a-CI may be formed on the 1-1st preliminary connecting electrode layer L1a-CI.

The step of forming the 1-1st preliminary connecting electrode layer L1a-CI may be performed through a deposition process of a first conductive material, and the step of forming the 2-1st preliminary connecting electrode layer L2a-CI may be performed through a deposition process of a second conductive material. The first conductive material and the second conductive material may include different materials. In an embodiment, for example, the first conductive material may include aluminum, and the second conductive material may include titanium. In an embodiment, both the deposition process of the first conductive material and the deposition process of the second conductive material may be performed through a sputtering process.

The preliminary connecting electrode CNE-I may include a first preliminary connecting portion P1-CI and the second connecting portion P2-C. The first preliminary connecting portion P1-CI may cover the entirety of the third preliminary auxiliary portion P3-A1 of the preliminary auxiliary electrode AXE-I. A portion of the first preliminary connecting portion P1-CI may be formed to overlap a portion of the contact hole CNT in a plan view. That is, the preliminary connecting electrode CNE-I may overhang. The “overhang” may mean that the deposited preliminary connecting electrode CNE-I protrudes toward the portion overlapping the contact hole CNT in a plan view as a large amount of material is deposited on the upper portion of the insulating layer ISL in the deposition process of the preliminary connecting electrode CNE-I. In this embodiment, the first preliminary connecting portion P1-CI may include a portion of the 1-1st preliminary connecting electrode layer L1a-C (hereinafter, referred to as the 1-1st preliminary sub-portion 11-1) disposed on the insulating layer ISL and a portion of the 2-1st preliminary connecting electrode layer L2a-CI (hereinafter, referred to as the 2-1st preliminary sub-portion 21-I) disposed on the insulating layer ISL.

The second connecting portion P2-C may be a portion formed in the contact hole CNT in a plan view. A shadow effect may occur due to the overhang of the preliminary connecting electrode CNE-I. Accordingly, the first conductive material and the second conductive material may not be deposited near the end of the lower side (i.e., bottom) of the contact hole CNT. The second connecting portion P2-C may cover only a portion of the first auxiliary portion P1-A. Accordingly, the preliminary connecting electrode CNE-I may not overlap the remaining portion other than a portion of the contact hole CNT that overlaps the overhang in a plan view. In an embodiment, the second connecting portion P2-C may include the 3-1st sub-portion 31 of the 1-1st preliminary connecting electrode layer L1a-CI and the 4-1st sub-portion 41 of the 2-1st preliminary connecting electrode layer L2a-CI.

According to this embodiment, in the step of forming the 1-1st preliminary connecting electrode layer L1a-CI, the 1-1st dummy electrode layer L1a-D may be formed together. In the step of forming the 1-1st preliminary connecting electrode layer L1a-CI, the first conductive material may not be deposited near the end of the lower side (i.e., bottom) of the contact hole CNT, and the first conductive material deposited near the bottom surface of the contact hole CNT may be formed to be the 1-1st dummy electrode layer L1a-D separated from the 1-1st preliminary connecting electrode layer L1a-CI.

The 1-1st dummy electrode layer L1a-D may include the same material as the 1-1st preliminary connecting electrode layer L1a-CI. The 1-1st dummy electrode layer L1a-D may be directly disposed on the second auxiliary portion P2-A.

According to this embodiment, in the step of forming the 2-1st preliminary connecting electrode layer L2a-CI, the 2-1st dummy electrode layer L2a-D may be formed together. In the step of forming the 2-1st preliminary connecting electrode layer L2a-CI, the second conductive material may not be deposited near the end of the lower side (i.e., bottom) of the contact hole CNT, and the second conductive material deposited near the bottom surface of the contact hole CNT may be formed to be the 2-1st dummy electrode layer L2a-D separated from the 2-1st preliminary connecting electrode layer L2a-CI.

The 2-1st dummy electrode layer L2a-D may include the same material as the 2-1st preliminary connecting electrode layer L2a-CI. The 2-1st dummy electrode layer L2a-D may be directly disposed on the 1-1st dummy electrode layer L1a-D.

Accordingly, in the step of forming the preliminary connecting electrode CNE-I, the dummy electrode DME including the 1-1st dummy electrode layer L1a-D and the 2-1st dummy electrode layer L2a-D may be formed together.

Referring to FIG. 9D, the display device manufacturing method according to this embodiment may include a step of providing a photoresist pattern PR.

The photoresist pattern PR may be formed on the preliminary connecting electrode CNE-I. The photoresist pattern PR may be formed by forming a photoresist layer on the preliminary connecting electrode CNE-I and thereafter making the photoresist layer subject to patterning by using a photo mask. Through the patterning process, the photoresist pattern PR overlapping the contact hole CNT in a plan view may be formed. A portion of the photoresist pattern PR may be formed in the contact hole CNT.

Referring to FIGS. 9D and 9E, the display device manufacturing method according to this embodiment may include the step of etching the preliminary connecting electrode CNE-I and the preliminary auxiliary electrode AXE-I. In this embodiment, the step of etching the preliminary connecting electrode CNE-I and the step of etching the preliminary auxiliary electrode AXE-I may be simultaneously performed.

The step of etching the preliminary connecting electrode CNE-I and the preliminary auxiliary electrode AXE-I may be performed by a dry etching method with the photoresist pattern PR as a mask.

Through the step of etching the preliminary connecting electrode CNE-I and the preliminary auxiliary electrode AXE-I, the connecting electrode CNE may be formed from the preliminary connecting electrode CNE-I, and the auxiliary electrode AXE may be formed from the preliminary auxiliary electrode AXE-I.

A portion of the preliminary connecting electrode CNE-I may be exposed from the photoresist pattern PR and may be removed, and the first connecting portion P1-C may be formed from the first preliminary connecting portion P1-CI. Accordingly, the connecting electrode CNE including the first and second connecting portions P1-C and P2-C may be formed.

In this embodiment, a portion of the 1-1st preliminary sub-portion 11-I of the 1-1st preliminary connecting electrode layer L1a-CI and a portion of the 2-1st preliminary sub-portion 21-I of the 2-1st preliminary connecting electrode layer L2a-CI may be removed. The 1-1st sub-portion 11 and the 2-1st sub-portion 21 may be formed from the 1-1st preliminary sub-portion 11-I and the 2-1st preliminary sub-portion 21-I, respectively. Accordingly, the 1-1st connecting electrode layer L1a-C and the 2-1st connecting electrode layer L2a-C may be formed from the 1-1st preliminary connecting electrode layer L1a-CI and the 2-1st preliminary connecting electrode layer L2a-CI, respectively, and the connecting electrode CNE including the 1-1st connecting electrode layer L1a-C and the 2-1st connecting electrode layer L2a-C may be formed. The first connecting portion P1-C may include the 1-1st sub-portion 11 of the 1-1st connecting electrode layer L1a-C and the 2-1st sub-portion 21 of the 2-1st connecting electrode layer L2a-C.

A portion of the third preliminary auxiliary portion P3-AI of the preliminary auxiliary electrode AXE-I may be exposed from the photoresist pattern PR and may be removed, and the third auxiliary portion P3-A may be formed from the third preliminary auxiliary portion P3-AI. Accordingly, the auxiliary electrode AXE including the first to third auxiliary portions P1-A, P2-A, and P3-A may be formed. A portion of the upper surface U-I of the insulating layer ISL may be exposed from the auxiliary electrode AXE.

The outer surface O-C of the connecting electrode CNE and the outer surface O-A of the auxiliary electrode AXE may be substantially aligned with each other. The outer surface O-C of the connecting electrode CNE may be included in the first connecting portion P1-C, and the outer surface O-A of the auxiliary electrode AXE may be included in the third auxiliary portion P3-A.

In an embodiment, the step of etching the preliminary connecting electrode CNE-I and the preliminary auxiliary electrode AXE-I may be performed through batch etching. That is, through one dry etching process, the connecting electrode CNE and the auxiliary electrode AXE may be formed from the preliminary connecting electrode CNE-I and the preliminary auxiliary electrode AXE-I, respectively.

Referring to FIGS. 9E and 9F, the display device manufacturing method according to this embodiment may include a step of removing the photoresist pattern PR. The connecting electrode CNE, the auxiliary electrode AXE, and the dummy electrode DME formed through the steps of FIGS. 9A to 9F may correspond to the connecting electrode CNE, the auxiliary electrode AXE, and the dummy electrode DME described above with reference to FIG. 7.

In this embodiment, the connecting electrode CNE may be electrically connected with the semiconductor pattern SP through the auxiliary electrode AXE. The auxiliary electrode AXE according to this embodiment may be provided in the form of a thin film and may be formed by a deposition process capable of providing excellent step coverage, and thus even though the connecting electrode CNE is formed in a shape disconnected from the semiconductor pattern SP in the contact hole CNT, the connecting electrode CNE may be electrically connected with the semiconductor pattern SP through the auxiliary electrode AXE. Accordingly, even though the shadow effect occurs due to the overhang in the process of forming the connecting electrode CNE, the connecting electrode CNE may be stably connected to the semiconductor pattern SP through the auxiliary electrode AXE.

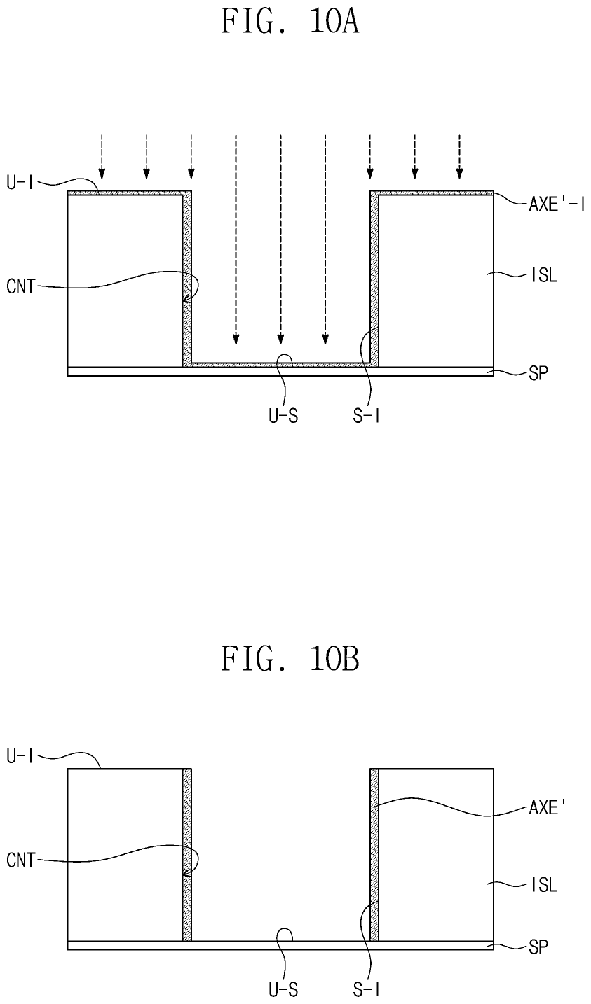

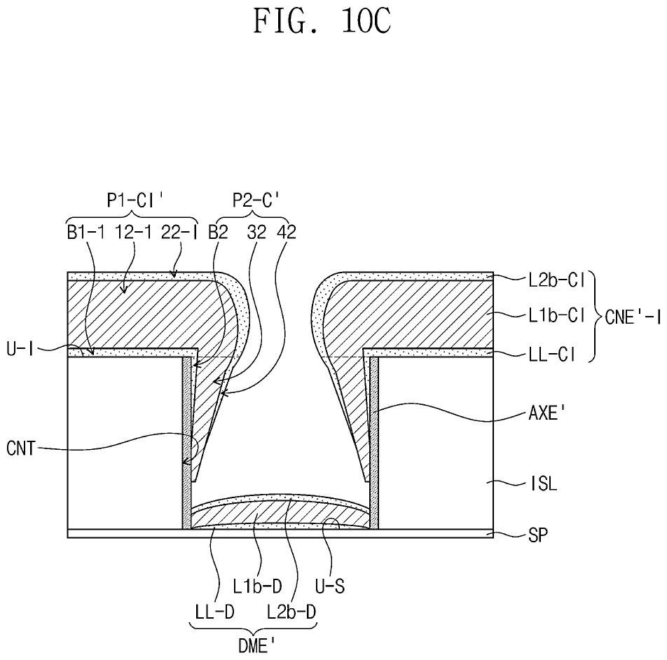

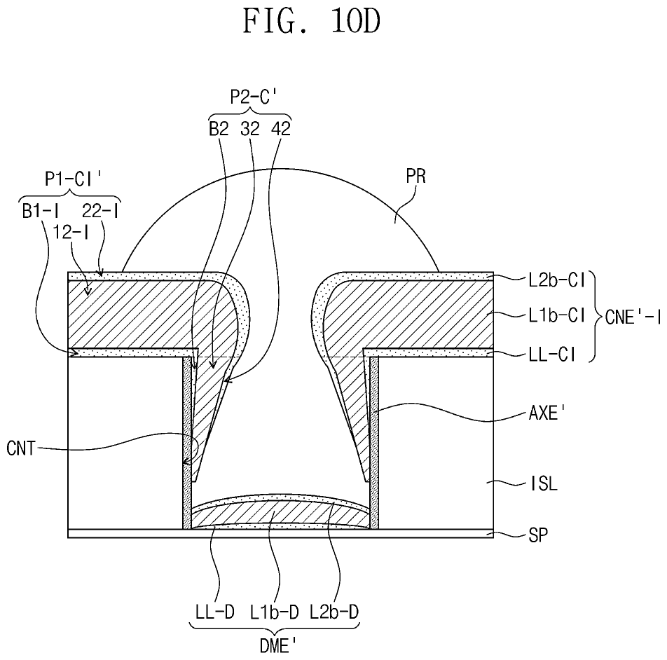

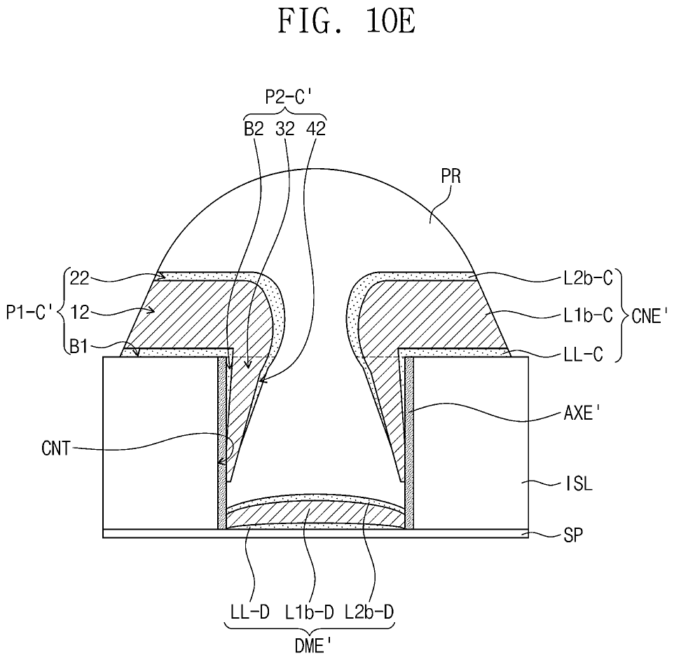

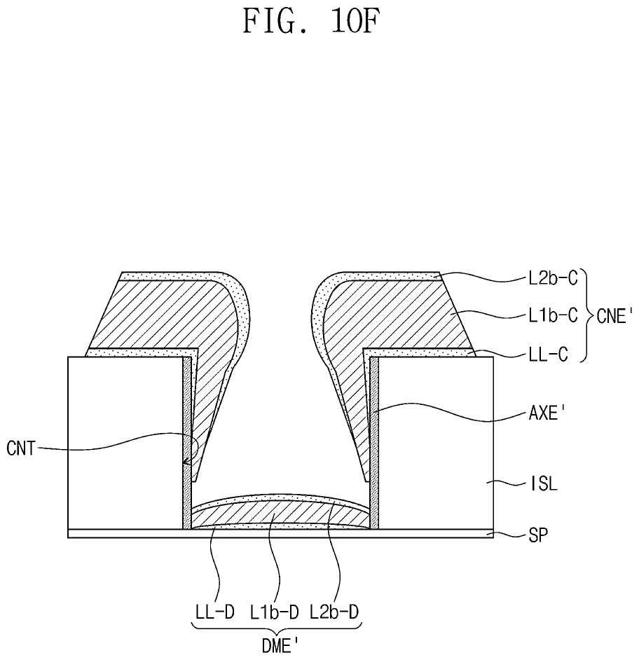

FIGS. 10A to 10F are sectional views illustrating some of the steps of a display device manufacturing method according to an embodiment of the present disclosure.

Referring to FIGS. 10A and 10B, the display device manufacturing method according to this embodiment may include a step of etching a preliminary auxiliary electrode AXE′-I before a step of forming a preliminary connecting electrode CNE′-I (refer to FIG. 10C) and after a step of forming the preliminary auxiliary electrode AXE′-I.

The step of etching the preliminary auxiliary electrode AXE′-I may be performed through a blanket anisotropic etching process. That is, a mask, such as a photoresist pattern, may not be used in the step of etching the preliminary auxiliary electrode AXE′-I according to this embodiment. The blanket anisotropic etching process of the preliminary auxiliary electrode AXE′-I may be performed by a dry etching method. In an embodiment, the dry etching of the preliminary auxiliary electrode AXE′-I may be performed through a plasma etching process. In an embodiment, for example, the dry etching of the preliminary auxiliary electrode AXE′-I may be performed through an inductively coupled plasma (“ICP”) etching process.

In the step of etching the preliminary auxiliary electrode AXE′-I, a portion of the preliminary auxiliary electrode AXE′-I disposed on the upper surface U-I of the insulating layer ISL and a portion of the preliminary auxiliary electrode AXE′-I disposed on the upper surface U-S of the semiconductor pattern SP exposed from the insulating layer ISL may be removed, and a portion of the preliminary auxiliary electrode AXE′-I that covers the inner surface S-I of the insulating layer ISL, which defines the contact hole CNT, and that extends in a substantially vertical direction along the inner surface S-I of the insulating layer ISL may remain. Accordingly, the auxiliary electrode AXE′ may be formed from the preliminary auxiliary electrode AXE′-I.

The auxiliary electrode AXE′ according to this embodiment may be provided in the form of a thin film that covers only the inner surface S-I of the insulating layer ISL (or, the sidewall of the contact hole CNT). Meanwhile, in this embodiment, the upper surface U-S of the semiconductor pattern SP may be exposed from the auxiliary electrode AXE′.

Referring to FIG. 10C, the display device manufacturing method according to this embodiment may include the step of forming the preliminary connecting electrode CNE′-I. The preliminary connecting electrode CNE′-I may be formed on the insulating layer ISL and the auxiliary electrode AXE′.

In this embodiment, the step of forming the preliminary connecting electrode CNE′-I may include a step of forming a lower preliminary connecting electrode layer LL-CI (or, a lower conductive layer), a step of forming a 1-2nd preliminary connecting electrode layer L1b-CI (or, a 1-2nd conductive layer), and a step of forming a 2-2nd preliminary connecting electrode layer L2b-CI (or, a 2-2nd conductive layer). The lower preliminary connecting electrode layer LL-CI may be formed on the insulating layer ISL and the auxiliary electrode AXE′, the 1-2nd preliminary connecting electrode layer L1b-CI may be formed on the lower preliminary connecting electrode layer LL-CI, and the 2-2nd preliminary connecting electrode layer L2b-CI may be formed on the 1-2nd preliminary connecting electrode layer L1b-CI.

The step of forming the preliminary connecting electrode layer L1b-CI may be performed through a deposition process of a first conductive material, and the step of forming the lower preliminary connecting electrode layer LL-CI and the step of forming the 2-2nd preliminary connecting electrode layer L2b-CI may be performed through a deposition process of a second conductive material. The first conductive material and the second conductive material may include different materials. In an embodiment, for example, the first conductive material may include aluminum, and the second conductive material may include titanium. In an embodiment, both the deposition process of the first conductive material and the deposition process of the second conductive material may be performed through a sputtering process.

The preliminary connecting electrode CNE′-I may include a first preliminary connecting portion P1-CI′ and the second connecting portion P2-C′. The first preliminary connecting portion P1-CI′ may cover the entirety of the upper surface U-I of the insulating layer ISL. A portion of the first preliminary connecting portion P1-CI′ may be formed to overlap the contact hole CNT in a plan view. That is, the preliminary connecting electrode CNE′-I may overhang. In this embodiment, the first preliminary connecting portion P1-CI′ may include a portion of the lower preliminary connecting electrode layer LL-CI disposed on the insulating layer ISL (hereinafter, referred to as the first lower preliminary sub-portion B1-I), a portion of the 1-2nd preliminary connecting electrode layer L1b-CI disposed on the insulating layer ISL (hereinafter, referred to as the 1-2nd preliminary sub-portion 12-1), and a portion of the 2-2nd preliminary connecting electrode layer L2b-CI disposed on the insulating layer ISL (hereinafter, referred to as the 2-2nd preliminary sub-portion 22-I).

The second connecting portion P2-C′ may be a portion formed in the contact hole CNT. A shadow effect may occur due to the overhang of the preliminary connecting electrode CNE′-I. Accordingly, the first conductive material and the second conductive material may not be deposited near the end of the lower side (i.e., bottom) of the contact hole CNT. The second connecting portion P2-C′ may cover only a portion of the auxiliary electrode AXE′. In this embodiment, the second connecting portion P2-C′ may include the second lower sub-portion B2 of the lower preliminary connecting electrode layer LL-CI, the 3-2nd sub-portion 32 of the 1-2nd preliminary connecting electrode layer L1b-CI, and the 4-2nd sub-portion 42 of the 2-2nd preliminary connecting electrode layer L2b-CI.

According to this embodiment, in the step of forming the lower preliminary connecting electrode layer LL-CI, the lower dummy electrode layer LL-D separated from the lower preliminary connecting electrode layer LL-CI may be formed together. The lower dummy electrode layer LL-D may include the same material as the lower preliminary connecting electrode layer LL-CI. The lower dummy electrode layer LL-D may be directly disposed on the exposed upper surface U-S of the semiconductor pattern SP.

In the step of forming the preliminary connecting electrode layer L1b-CI, the 1-2nd dummy electrode layer L1b-D separated from the 1-2nd preliminary connecting electrode layer L1b-CI may be formed together. The 1-2nd dummy electrode layer L1b-D may include the same material as the 1-2nd preliminary connecting electrode layer L1b-CI. The 1-2nd dummy electrode layer L1b-D may be directly disposed on the lower dummy electrode layer LL-D.

In the step of forming the preliminary connecting electrode layer L2b-CI, the 2-2nd dummy electrode layer L2b-D separated from the 2-2nd preliminary connecting electrode layer L2b-CI may be formed together. The 2-2nd dummy electrode layer L2b-D may include the same material as the 2-2nd preliminary connecting electrode layer L2b-CI. The 2-2nd dummy electrode layer L2b-D may be directly disposed on the 1-2nd dummy electrode layer L1b-D.

Accordingly, in the step of forming the preliminary connecting electrode CNE′-I, the dummy electrode DME′ including the lower dummy electrode layer LL-D, the 1-2nd dummy electrode layer L1b-D, and the 2-2nd dummy electrode layer L2b-D may be formed together.

Referring to FIG. 10D, the display device manufacturing method according to this embodiment may include a step of providing a photoresist pattern PR. The description given above with reference to FIG. 9D may be identically applied to the step of providing the photoresist pattern PR.

Referring to FIGS. 10E and 10F, the display device manufacturing method according to this embodiment may include a step of etching the preliminary connecting electrode CNE′-I. In this embodiment, the step of etching the preliminary connecting electrode CNE′-I may be performed after the auxiliary electrode AXE′ is formed.

The step of etching the preliminary connecting electrode CNE′-I may be performed by a dry etching method with the photoresist pattern PR as a mask.

Through the step of etching the preliminary connecting electrode CNE′-I, the connecting electrode CNE′ may be formed from the preliminary connecting electrode CNE′-I. A portion of the preliminary connecting electrode CNE′-I may be exposed from the photoresist pattern PR and may be removed, and the first connecting portion P1-C′ may be formed from the first preliminary connecting portion P1-CI′. Accordingly, the connecting electrode CNE′ including the first and second connecting portions P1-C′ and P2-C′ may be formed.

In this embodiment, the first lower preliminary sub-portion B1-I of the lower preliminary connecting electrode layer LL-CI, the 1-2nd preliminary sub-portion 12-I of the 1-2nd preliminary connecting electrode layer L1b-CI, and the 2-2nd preliminary sub-portion 22-I of the 2-2nd preliminary connecting electrode layer L2b-CI may be partially removed. The first lower sub-portion B1, the 1-2nd sub-portion 12, and the 2-2nd sub-portion 22 may be formed from the first lower preliminary sub-portion B1-I, the 1-2nd preliminary sub-portion 12-I, and the 2-2nd preliminary sub-portion 22-I, respectively. Accordingly, the lower connecting electrode layer LL-C, the 1-2nd connecting electrode layer L1b-C, and the 2-2nd connecting electrode layer L2b-C may be formed from the lower preliminary connecting electrode layer LL-CI, the 1-2nd preliminary connecting electrode layer L1b-CI, and the 2-2nd preliminary connecting electrode layer L2b-CI, respectively. Accordingly, the connecting electrode CNE′ including the lower connecting electrode layer LL-C, the 1-2nd connecting electrode layer L1b-C, and the 2-2nd connecting electrode layer L2b-C may be formed. The first connecting portion P1-C′ may include the first lower sub-portion B1 of the lower connecting electrode layer LL-C, the 1-2nd sub-portion 12 of the 1-2nd connecting electrode layer L1b-C, and the 2-2nd sub-portion 22 of the 2-2nd connecting electrode layer L2b-C.

Referring to FIGS. 10E and 10F, the display device manufacturing method according to this embodiment may include a step of removing the photoresist pattern PR. The connecting electrode CNE′, the auxiliary electrode AXE′, and the dummy electrode DME′ formed through the steps of FIGS. 10A to 10F may correspond to the connecting electrode CNE′, the auxiliary electrode AXE′, and the dummy electrode DME′ described above with reference to FIG. 8.

In this embodiment, the connecting electrode CNE′ may be electrically connected with the semiconductor pattern SP through the auxiliary electrode AXE′ and the dummy electrode DME′. The auxiliary electrode AXE′ according to this embodiment may be provided in the form of a thin film and may be formed by a deposition process capable of providing excellent step coverage. Accordingly, the auxiliary electrode AXE′ may include a portion making contact with both the connecting electrode CNE′ and the dummy electrode DME′. Even though the connecting electrode CNE′ is formed in a shape disconnected from the semiconductor pattern SP in the contact hole CNT, the connecting electrode CNT′ may be electrically connected with the semiconductor pattern SP through the auxiliary electrode AXE′. Accordingly, even though the shadow effect occurs due to the overhang in the process of forming the connecting electrode CNE′, the connecting electrode CNE′ may be stably connected to the semiconductor pattern SP through the auxiliary electrode AXE′.

According to the present disclosure, in the display device and the manufacturing method thereof, the auxiliary electrode may be disposed on the sidewall of the contact hole. Accordingly, a defect in connection between the electrodes may be prevented or reduced.

In addition, in the display device and the manufacturing method thereof according to the present disclosure, the connecting electrode may be stably connected with the semiconductor pattern. Accordingly, stable electrical characteristics may be secured.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a circuit layer; and
a light emitting element disposed on the circuit layer,
wherein the circuit layer includes:
a semiconductor pattern;
an insulating layer defining a contact hole therein to expose a portion of the semiconductor pattern;
a connecting electrode disposed on the insulating layer and partially disposed in the contact hole; and
an auxiliary electrode at least partially disposed in the contact hole and contacting with the connecting electrode and the semiconductor pattern, and
wherein the connecting electrode does not overlap a portion of the contact hole in a plan view.

2. The display device of claim 1, wherein the auxiliary electrode includes:
a first auxiliary portion, which contacts with an inner surface of the insulating layer defining the contact hole and covers an entirety of the inner surface of the insulating layer;
a second auxiliary portion, which contacts with the portion of the semiconductor pattern exposed from the insulating layer and covers an entirety of the portion of the semiconductor pattern; and
a third auxiliary portion, which contacts with a portion of an upper surface of the insulating layer.

3. The display device of claim 2, wherein the connecting electrode includes:
a first connecting portion, which contacts with the third auxiliary portion; and
a second connecting portion, which extends downward from the first connecting portion and contacts with the first auxiliary portion.

4. The display device of claim 3, wherein an outer surface of the auxiliary electrode and an outer surface of the connecting electrode are aligned with each other,
wherein the outer surface of the auxiliary electrode is included in the third auxiliary portion, and
wherein the outer surface of the connecting electrode is included in the first connecting portion.

5. The display device of claim 2, wherein the connecting electrode includes:
a 1-1st connecting electrode layer disposed on the auxiliary electrode and including aluminum; and
a 2-1st connecting electrode layer disposed on the 1-1st connecting electrode layer and including titanium.

6. The display device of claim 5, further comprising:
a dummy electrode disposed on the second auxiliary portion in the contact hole,
wherein the dummy electrode includes:
a 1-1st dummy electrode layer spaced apart from the 1-1st connecting electrode layer and including a same material as the 1-1st connecting electrode layer; and
a 2-1st dummy electrode layer disposed on the 1-1st dummy electrode layer, spaced apart from the 2-1st connecting electrode layer and including a same material as the 2-1st connecting electrode layer.

7. The display device of claim 1, wherein all of the auxiliary electrode is disposed in the contact hole and covers an entirety of an inner surface of the insulating layer defining the contact hole, and
wherein the semiconductor pattern includes a portion exposed from the auxiliary electrode.

8. The display device of claim 7, wherein the connecting electrode includes:
a lower connecting electrode layer, which contacts with an upper surface of the insulating layer and includes titanium;
a 1-2nd connecting electrode layer disposed on the lower connecting electrode layer and including aluminum; and
a 2-2nd connecting electrode layer disposed on the 1-2nd connecting electrode layer and including titanium.

9. The display device of claim 8, further comprising:
a dummy electrode disposed on an upper surface of the semiconductor pattern in the contact hole,
wherein an edge of the dummy electrode makes contact with the auxiliary electrode.

10. The display device of claim 9, wherein the dummy electrode includes:
a lower dummy electrode layer contacting with the upper surface of the semiconductor pattern, spaced apart from the lower connecting electrode layer and including the same material as the lower connecting electrode layer;
a 1-2nd dummy electrode layer disposed on the lower dummy electrode layer, spaced apart from the 1-2nd connecting electrode layer and including a same material as the 1-2nd connecting electrode layer; and
a 2-2nd dummy electrode layer disposed on the 1-2nd dummy electrode layer, spaced apart from the 2-2nd connecting electrode layer and including a same material as the 2-2nd connecting electrode layer.

11. The display device of claim 1, wherein the auxiliary electrode includes tungsten.

12. The display device of claim 1, wherein an inner surface of the insulating layer defining the contact hole has a slope of 80 degrees to 90 degrees with respect to an upper surface of the semiconductor pattern, and
wherein the contact hole has a width greater than 0 micrometer and less than or equal 2.0 micrometers in a sectional view.

13. A display device comprising:
a circuit layer; and
a light emitting element disposed on the circuit layer,
wherein the circuit layer includes:
a semiconductor pattern;
an insulating layer defining a contact hole therein to expose a portion of the semiconductor pattern;
a connecting electrode disposed on the insulating layer and partially disposed in the contact hole;
a dummy electrode disposed on the semiconductor pattern in the contact hole and spaced apart from the connecting electrode; and
an auxiliary electrode at least partially disposed in the contact hole and contacting with the connecting electrode and the dummy electrode.

14. A method for manufacturing a display device, the method comprising:
providing a semiconductor pattern and an insulating layer defining a contact hole therein to expose a portion of the semiconductor pattern;
forming a preliminary auxiliary electrode on the insulating layer;
forming a preliminary connecting electrode on the insulating layer;
etching the preliminary connecting electrode to form a connecting electrode partially disposed in the contact hole; and
etching the preliminary auxiliary electrode to form an auxiliary electrode at least partially disposed in the contact hole,
wherein the auxiliary electrode makes contact with the connecting electrode and the semiconductor pattern, and
wherein the connecting electrode does not overlap a portion of the contact hole in a plan view.

15. The method of claim 14, further comprising:
forming, on the preliminary connecting electrode, a photoresist pattern overlapping the contact hole before the etching of the preliminary connecting electrode and after the forming of the preliminary connecting electrode,
wherein the etching of the preliminary auxiliary electrode is simultaneously performed together with the etching of the preliminary connecting electrode.

16. The method of claim 15, wherein the forming of the preliminary connecting electrode includes:
forming, on the preliminary auxiliary electrode, a 1-1st conductive layer including aluminum; and
forming, on the 1-1st conductive layer, a 2-1st conductive layer including titanium.

17. The method of claim 14, wherein the etching of the preliminary auxiliary electrode is performed before the forming of the preliminary connecting electrode and after the forming of the preliminary auxiliary electrode, and
wherein the etching of the preliminary auxiliary electrode is performed through a blanket anisotropic etching process.

18. The method of claim 17, wherein the forming of the preliminary connecting electrode includes:
forming, on the insulating layer, a lower conductive layer including titanium;
forming, on the lower conductive layer, a 1-2nd conductive layer including aluminum; and
forming, on the 1-2nd conductive layer, a 2-2nd conductive layer including titanium.

19. The method of claim 14, wherein a dummy electrode including a same material as the connecting electrode is additionally formed in the forming of the preliminary connecting electrode, and the dummy electrode is disposed in the contact hole and spaced apart from the connecting electrode.

20. The method of claim 14, wherein the forming of the preliminary auxiliary electrode is performed through a chemical vapor deposition process.
